(19) United States
(12) Patent Application Publication
(10) Pub. No.: US 2025/0238564 A1
(43) Pub. Date: Jul. 24, 2025

(54) ARTIFICIAL INTELLIGENCE DRIVEN PROPERTY DESIGN

(71) Applicant: Bay Scenery, Inc., Mountain View, CA (US)

(72) Inventors: Ali TEHRANCHI, San Jose, CA (US); Firooz KESHAVARZI, San Jose, CA (US); Behdad BOLOUHAR, San Jose, CA (US); Mohammadamin JAHANPOUR, Windsor (CA)

(73) Assignee: Bay Scenery, Inc., Mountain View, CA (US)

(21) Appl. No.: 18/421,921

(22) Filed: Jan. 24, 2024

(51) Int. Cl. G06F 30/13; G06F 30/27; G06N 20/00

(52) U.S. Cl. CPC G06F 30/13; G06F 30/27; G06N 20/00

(57) ABSTRACT

A data processing system implements receiving, from a design application, property location information associated with a property and a first natural language prompt describing a design for a construction project associated with the property; accessing a plurality of data sources to obtain information associated with the property; analyzing the information associated with the property using one or more machine learning models to generate a preliminary site plan, the preliminary site plan representing a current state of the property; analyzing the first natural language prompt and the preliminary site plan using one or more machine learning models to generate a proposed design for the construction project; causing the design application to present the proposed design on a user interface of the design application; receiving an indication from the design application to finalize the proposed design; and generating content for the proposed design using the one or more machine learning models.

### BACKGROUND

The construction design phase is a critical step in construction projects. The construction projects may be commercial or residential projects and may include but are not limited to general contracting, landscape contracting, and swimming pool construction projects. The design phase is a complex and time-consuming process that involves understanding client needs, budget, preferences, site-specific conditions, and designing plans that satisfy these requirements while also satisfying any legal and engineering requirements, such as zoning approvals, building permits, and environmental clearances. Currently, the design phase involves numerous manual steps that are expensive and time consuming, which increases the cost and time to complete construction projects. Hence, there is a need for improved systems and methods that provide means for automatically generating designs for construction projects that satisfy the various requirements associated with these designs.

### SUMMARY

An example data processing system according to the disclosure includes a processor and a memory storing executable instructions. The instructions when executed cause the processor alone or in combination with other processors to perform operations including receiving, from a design application, property location information associated with a property and a first natural language prompt describing a design for a construction project associated with the property; accessing a plurality of data sources to obtain information associated with the property; analyzing the information associated with the property using one or more machine learning models to generate a preliminary site plan of the property, the preliminary site plan representing a current state of the property; analyzing the first natural language prompt and the preliminary site plan using one or more machine learning models to generate a proposed design for the construction project; causing the design application to present the proposed design on a user interface of the design application; receiving an indication from the design application to finalize the proposed design; and generating content for the proposed design using the one or more machine learning models.

An example method implemented in a data processing system includes receiving, from a design application, property location information associated with a property and a first natural language prompt describing a design for a construction project associated with the property; accessing a plurality of data sources to obtain information associated with the property; analyzing the information associated with the property using one or more machine learning models to generate a preliminary site plan of the property, the preliminary site plan representing a current state of the property; analyzing the first natural language prompt and the preliminary site plan using one or more machine learning models to generate a proposed design for the construction project; causing the design application to present the proposed design on a user interface of the design application; receiving an indication from the design application to finalize the proposed design; and generating content for the proposed design using the one or more machine learning models.

An example data processing system according to the disclosure includes a processor and a memory storing executable instructions. The instructions when executed cause the processor alone or in combination with other processors to perform operations including obtaining property location information and a natural language prompt via a user interface of a design application on a client device, the natural language prompt describing a design for a construction project associated with a property, and the property location information identifying a location of the property; accessing a plurality of data sources to obtain information associated with the property; analyzing the information associated with the property using one or more machine learning models to generate a preliminary site plan of the property, the preliminary site plan representing a current state of the property; analyzing the first natural language prompt and the preliminary site plan using one or more machine learning models to generate a proposed design for the construction project; presenting the proposed design on the user interface of the design application on the client device; receiving, via the user interface of the design application, an indication to finalize the proposed design; generating content for the proposed design using the one or more machine learning models; and presenting the content for the proposed design on the user interface of the design application on the client device.

An example data processing system according to the disclosure includes a processor and a memory storing executable instructions. The instructions when executed cause the processor alone or in combination with other processors to perform operations including receiving, from a user interface of a design application, a first natural language prompt comprising location information for a property and a design for a construction project associated with the property; retrieving property information from a plurality of data sources using a plurality of data retrieval modules operating in parallel to retrieve a portion of the property information; training a first black box artificial intelligence (AI) model based on the property information; generating a preliminary site plan of the property using the first black box AI model, the preliminary site plan representing a current state of the property; training a second black box AI model based on the preliminary site plan; analyzing the first natural language prompt using the second AI black box model to generate a proposed design for the construction project; causing the user interface of the design application to present the proposed design for the construction project; receiving a second natural language prompt from the user interface of the design application, the second natural language prompt requesting one or more changes to be made to the proposed design; analyzing the second natural language prompt using the second AI black box model to generate a revised design for the construction project; receiving an indication from the user interface to finalize the revised design and to output one or more content items based on the finalized design; training a third black box AI model based on the revised design; and generating the one or more content items using the third black box AI model.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

### BRIEF DESCRIPTION OF THE DRAWINGS

The drawing figures depict one or more implementations in accord with the present teachings, by way of example only, not by way of limitation. In the figures, like reference numerals refer to the same or similar elements. Furthermore, it should be understood that the drawings are not necessarily to scale.

FIG. 1 is a diagram of an example property design pipeline that implements the techniques for artificial intelligence generated property design content described herein are implemented.

FIG. 2 is a diagram of an example computing environment in which the property design pipeline shown in FIG. 1 is implemented.

FIG. 3A is a diagram showing an example implementation of the data sources and the data capture layer of the property design pipeline shown in FIG. 1.

FIG. 3B is a diagram showing another example implementation of the data capture layer of the property design pipeline shown in the preceding figures.

FIG. 3C is a diagram showing an example implementation of the design customization layer of the property design pipeline shown in FIG. 1.

FIG. 3D is a diagram showing an example implementation of the design routing layer of the property design pipeline shown in FIG. 1.

FIGS. 4A-4I are diagrams showing an example user interface of a design application according to the techniques disclosed herein.

FIG. 5A is a flow chart of another example process for automatically obtaining a contextually relevant frame for an image according to the techniques disclosed herein.

FIG. 5B is a flow chart of another example process for automatically obtaining a contextually relevant frame for an image according to the techniques disclosed herein.

FIG. 5C is a flow chart of another example process for automatically obtaining a contextually relevant frame for an image according to the techniques disclosed herein.

FIG. 6 is a block diagram showing an example software architecture, various portions of which may be used in conjunction with various hardware architectures herein described, which may implement any of the described features.

FIG. 7 is a block diagram showing components of an example machine configured to read instructions from a machine-readable medium and perform any of the features described herein.

FIG. 8 is a flow diagram of an example of a current property design process that includes estimates for each of the stages of the process.

### DETAILED DESCRIPTION

Systems and methods for automatically generating property designs using artificial intelligence (AI) are provided. These techniques provide a technical solution to the technical problem of automating the design process. Currently, the design process is manual, labor-intensive, and costly process that significantly increase the cost and time to complete construction projects. The techniques herein utilize AI to generate content for numerous phases of the development of a property design, including generating example layouts, plans, rendering, and/or other documents that would typically be drafted manually by human developers. A technical benefit of this approach is that the models used to generate the design content consider client needs, budget, preferences, and site-specific conditions to generate the design content. The techniques herein generate customized designs for residential construction projects, commercial construction projects, and/or public construction projects. Residential construction projects can include but are not limited to single or multiple family dwellings. Commercial construction projects can include but are not limited to office spaces, research facilities, restaurants, retail establishments, and shopping malls and centers. Public construction projects can include but are not limited to governmental, educational, transit, and healthcare facilities. The customized designs can include structural design for building and/or landscaping design for outdoor spaces. These designs can incorporate existing structures, landscaping, and/or landscape or topographical features. Furthermore, these techniques also generate a cost estimate for the design should the user decide to construct a particular design.

The techniques herein provide a user interface that enables the user to interact with the models using natural language prompts entered into chat user interface. A technical benefit of this approach is that users can describe in natural language the construction project for which the user would like to obtain a proposed design. The techniques herein implement a property design pipeline that automatically analyzes the natural language prompts input by users to determine the user intent to generate an appropriate design. The property design pipeline interacts with the user through a user interface of a design application on a client device of the user. The natural language prompt describes features of the design, such as but not limited to the type of structures to be constructed, a preferred location of these structures, landscaping preferences, building and/or landscaping styes, color palettes, and/or other features of the design to be generated. The user also provides location information identifying the location of the property for which the design is to be created. The location information can include, but is not limited to a street address, an Assessor's Parcel Number (APN), geographical coordinates, or other information identifying the location of the property. In response to receiving the location information and the natural language prompt, the property design pipeline automatically obtains information from various data sources based on property address information provided by the user to access numerous sources of information, including but not limited to various combinations of satellite and aerial imagery, topological information, public and private property data, official property survey data, local building regulations, and/or other sources of data. The information obtained by the various data sources is analyzed using one or more machine learning models trained to generate a proposed design based on the natural language prompt and the data collected from the various data sources. The property design pipeline performs a comprehensive analysis of the property based on the data collected from the various data sources and generates the proposed design to comply with all applicable building codes. The property design pipeline implements a parallel processing design in which many of the tasks performed by the various components of the pipeline are performed by AI driven modules that collect and analyze data and generate content in parallel with other processed to substantially reduce the amount of time that the system takes to generate the proposed design. The proposed design is then presented to the user on the user interface of the design application.

The user can review the proposed design and interact with the property design pipeline through additional natural language prompts to cause the property design pipeline revise and further customize the proposed design. The property design pipeline generates renderings, plans, and/or other representations of the proposed design. Once the design is finalized, the property design pipeline generates content for the project design, such as but not limited to two-dimensional (2D) and/or three-dimensional (3D) models of the design project, point cloud representations of the design, detailed blueprints, and a detailed cost estimate for the construction project. A technical benefit of this approach is that property design pipeline can generate a customized property design in a matter of minutes or hours compared with the current approaches to property design which can take weeks and/or months to prepare a design. Another technical benefit of this approach is that the computing resources required to generate a property design because the user is able to provide a detailed description of the desired design and to provide immediate feedback to customize the design. In contrast, the current manual approach would require the designers to repeatedly, manually modify the design in the design application in response to user feedback, which would require significantly more computing resources utilized to generate the design.

The property design pipeline also learns about the user from the user's interactions with the property design pipeline. The property design pipeline learns design features that are preferred by the user and uses this information to provide design proposals that satisfy the unique style of the user. The property design pipeline can also learn the cost estimate process preferred by the user and apply that process to the subsequent designs by user. A technical benefit of this approach is that the models used by the property design pipeline learn about the user over time, thereby improving the inferences by these models. Consequently, the proposed designs are likely to require fewer changes, which can significantly reduce the computing resources required to generate a proposed design because the user is less likely to prompt the property design pipeline to substantially alter the proposed designs. These and other technical benefits of the techniques disclosed herein will be evident from the discussion of the example implementations that follow.

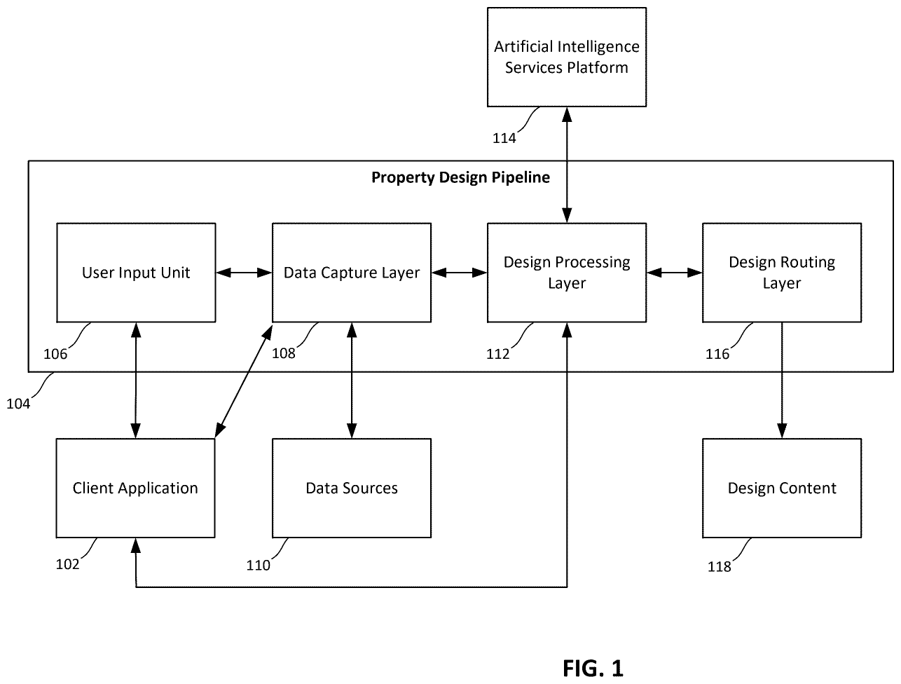

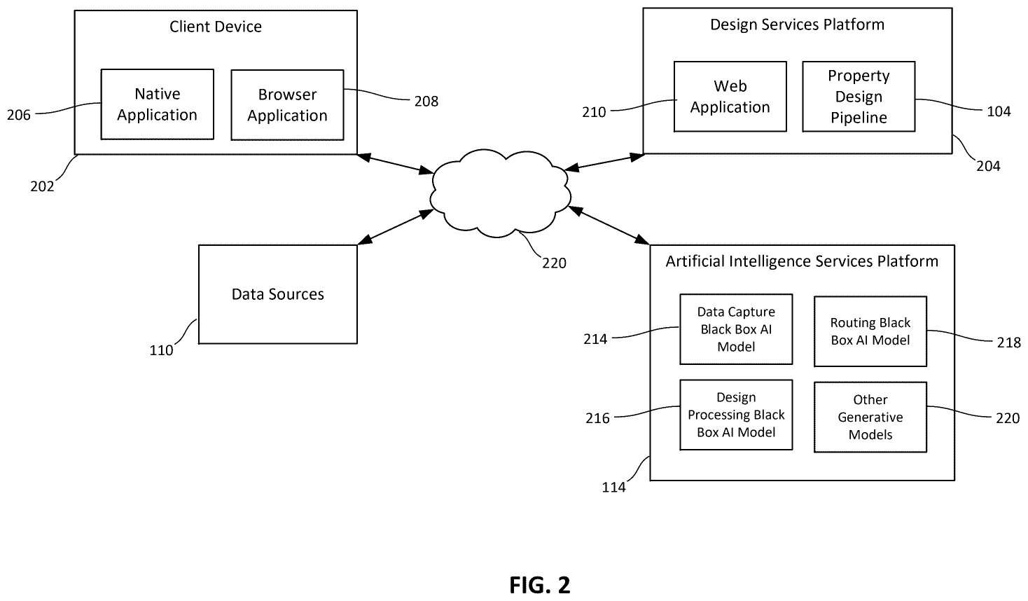

FIG. 1 is a diagram of an example property design pipeline 104 that implements the techniques for artificial intelligence generated property design content described herein are implemented. The property design pipeline 104 is implemented by a cloud-based design services platform, such as the design services platform 204, in some implementations. In other implementations, the property design pipeline 104 is implemented by a design application on a client device, such as the client device 202 shown in FIG. 2. The property design pipeline 104 includes a user input unit 106, a data capture layer 108, a design processing layer 112, and a design routing layer 116. The data capture layer 108, the design processing layer 112, and the design routing layer 116 are each implemented using back box AI models as discussed in detail in the examples which follow. Furthermore, the collected and/or generated by each layer is available to the other layers of the property design pipeline 104.

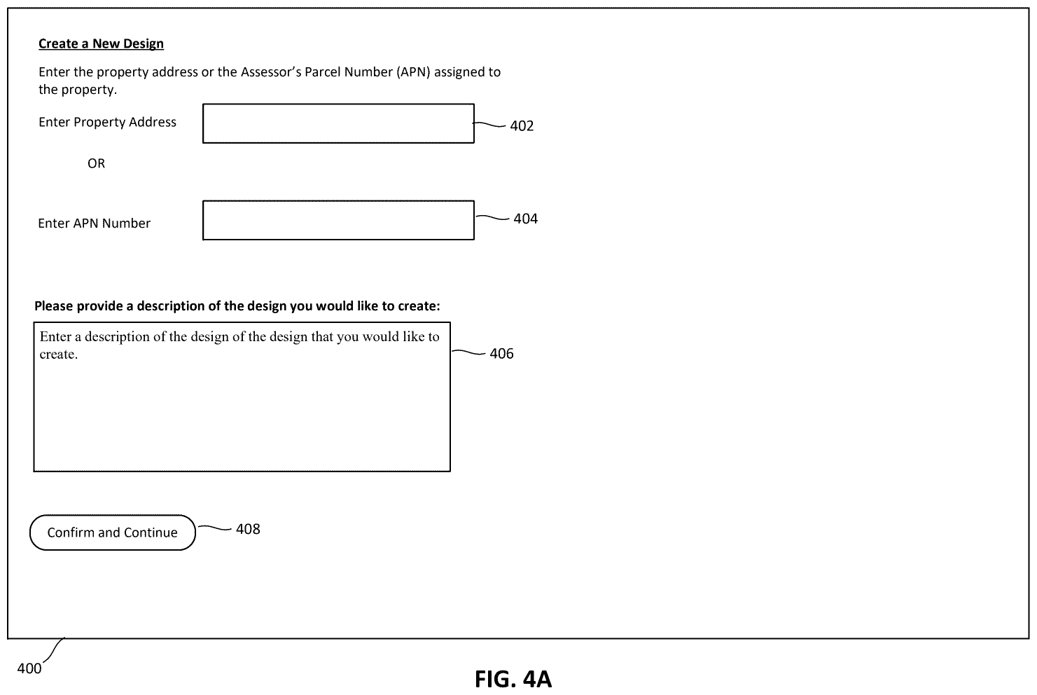

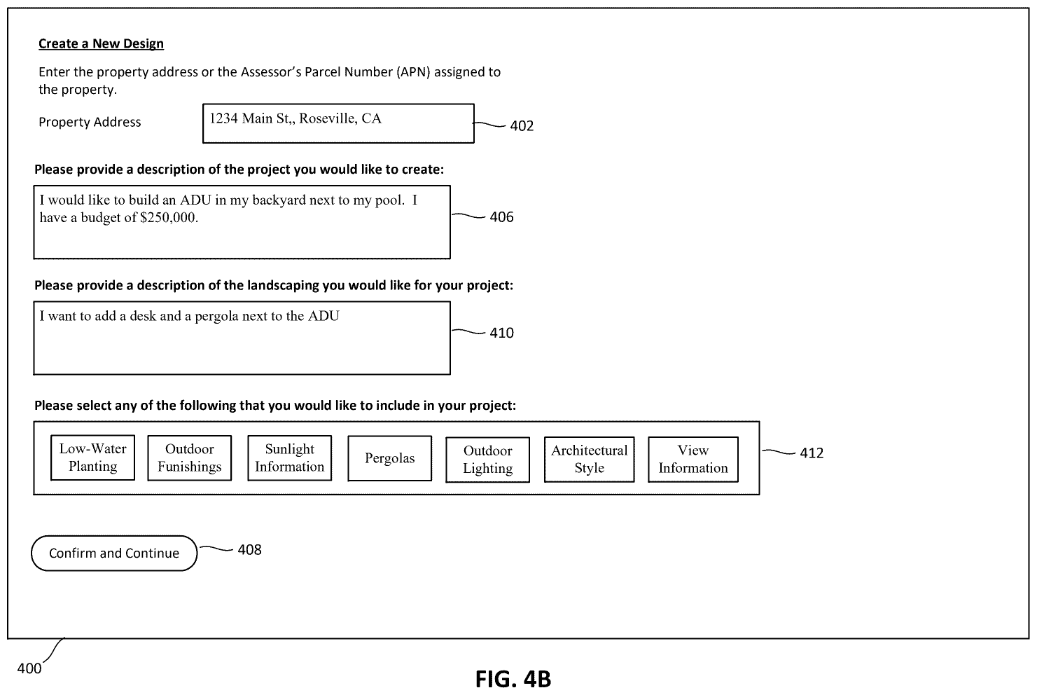

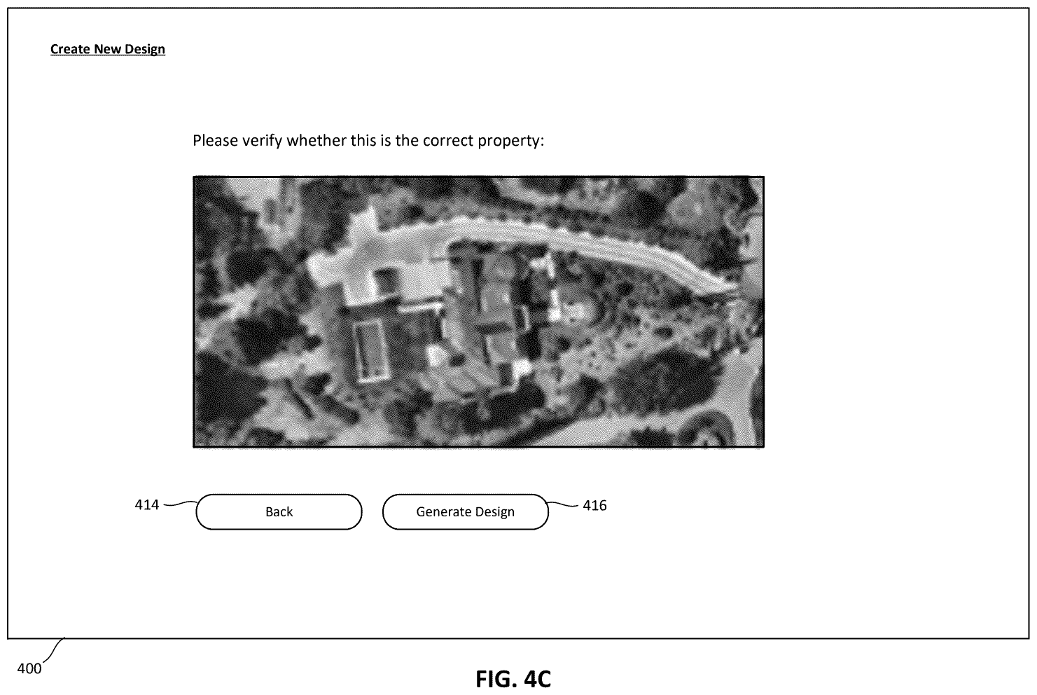

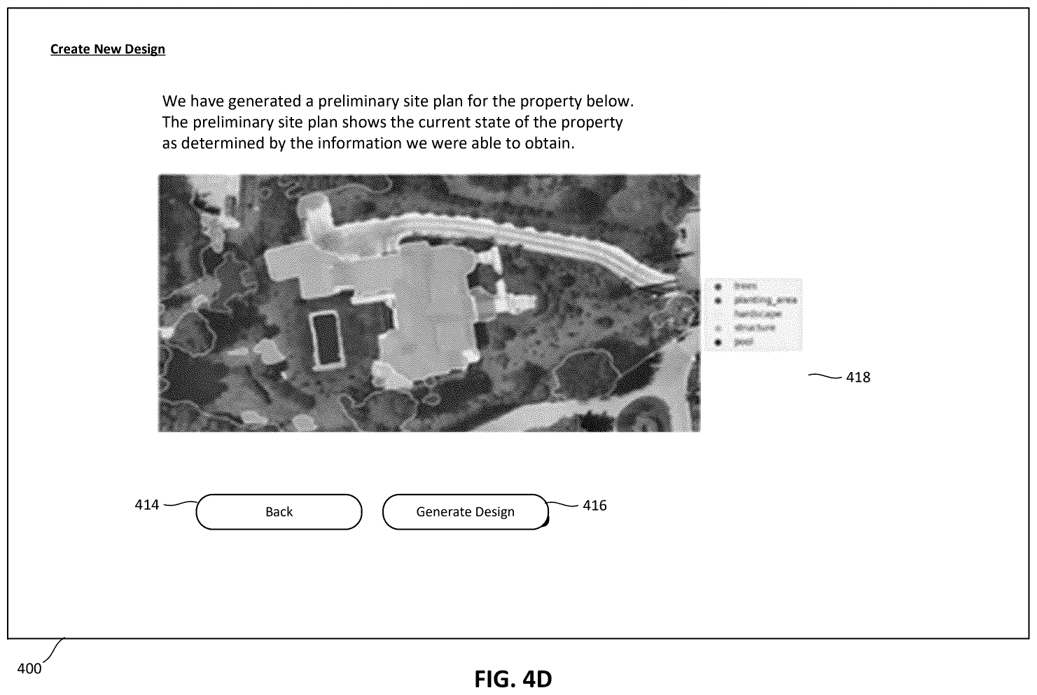

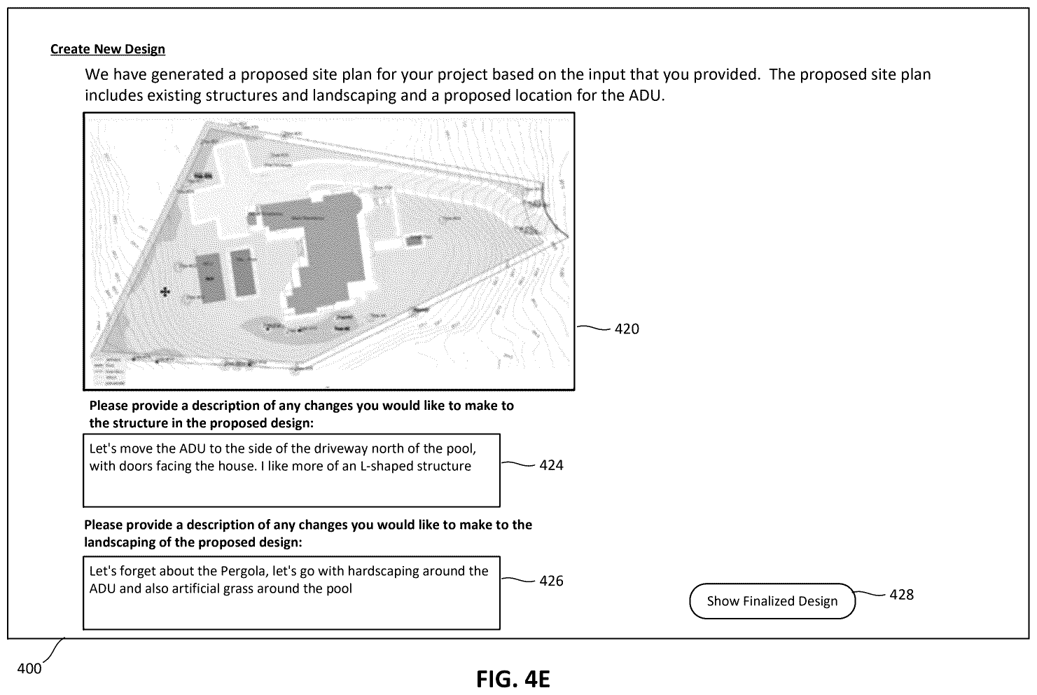

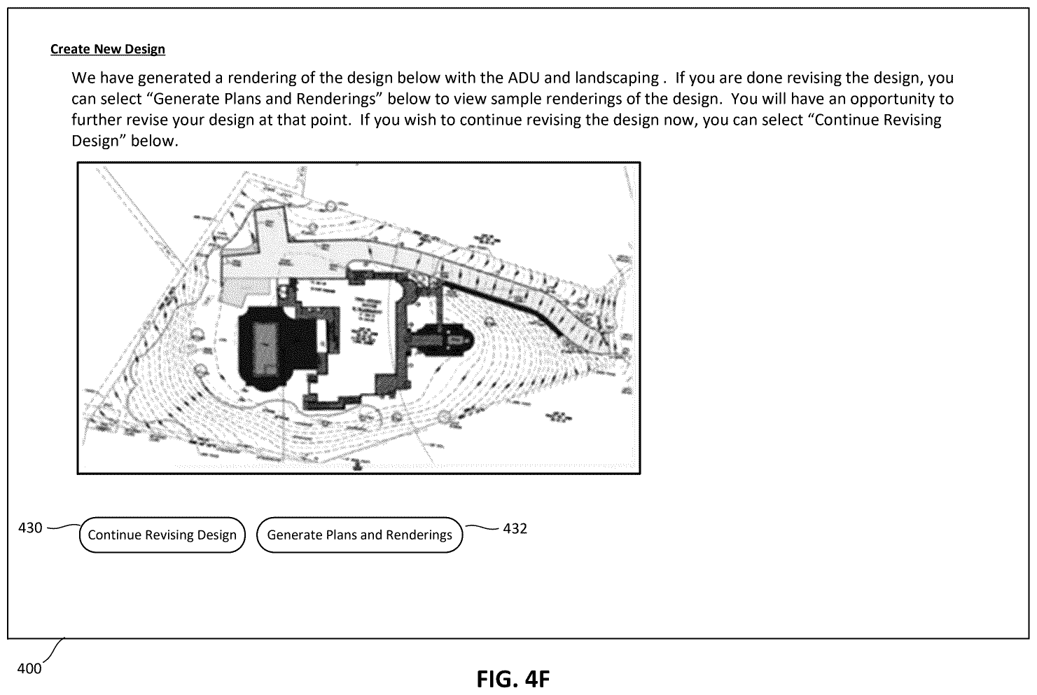

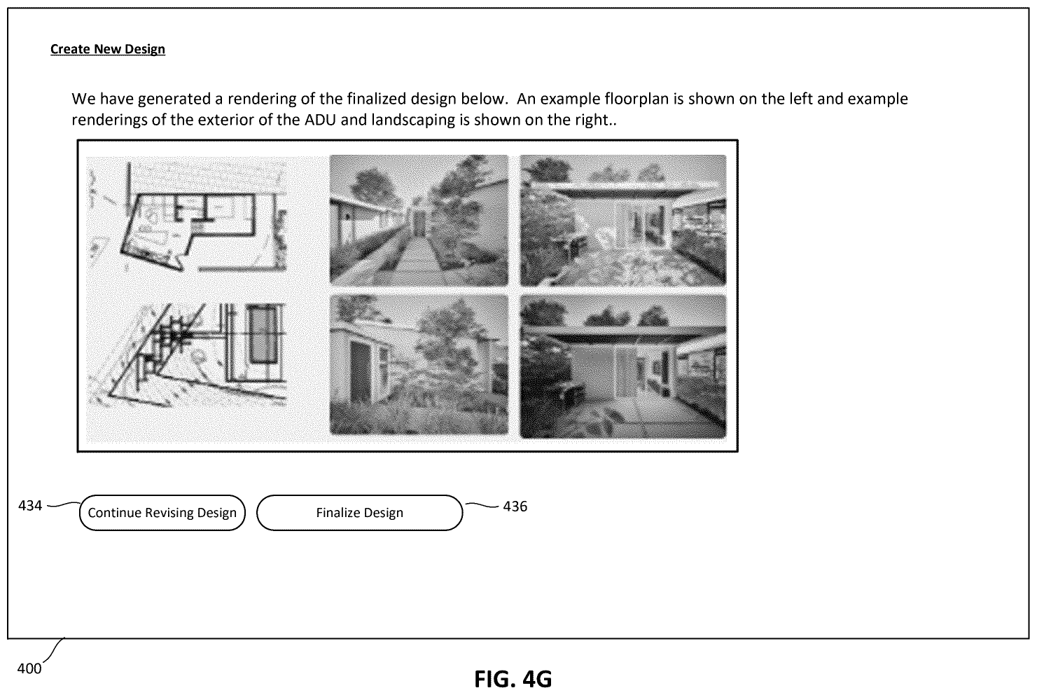

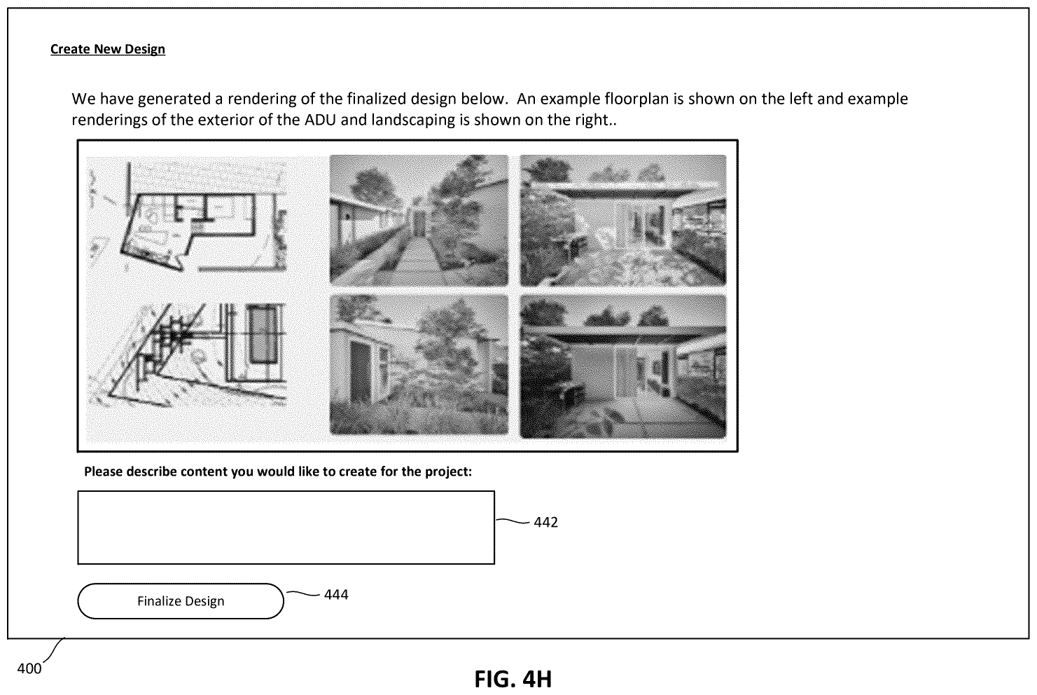

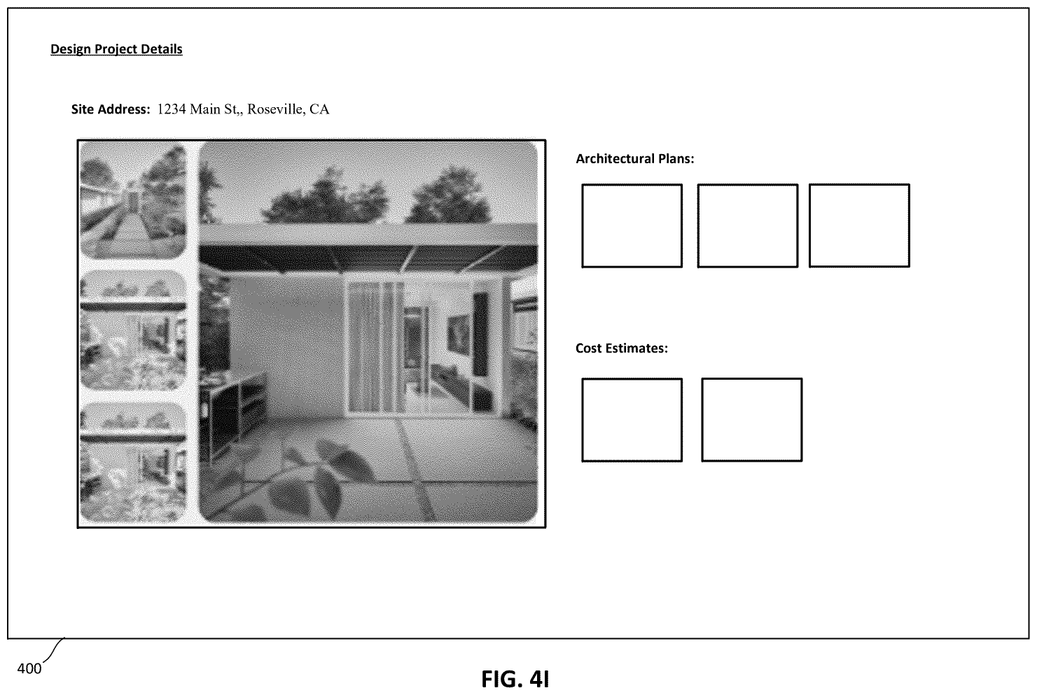

The property design pipeline 104 receives user inputs, such as property location information and natural language prompts, from a client application 102. The client application 102 is a design application that utilizes the property design pipeline 104 to generate and/or modify property designs using the property design pipeline 104. The client application 102 may be implemented as a web-based application on a cloud-based design platform, such as the design services platform 204 shown in FIG. 2, or as a native application a client device, such as the native application 206 of the client device 202 shown in FIG. 2. The client application 102 provides a user interface that enables users to collaborate with the property design pipeline 104 to create new designs for construction projects and/or modify existing designs. The client application 102 may be used by various types of users, including homeowners, designers, architects, and builders. The specific functionality provided by the client application 102 may depend at least in part on the type of user. The user interface enables the user to provide natural language prompts to the property design pipeline 104 that describe the construction project for which a new project design is to be created and/or modify an existing design. Examples of such a user interface are shown in FIGS. 4A-4I, which are discussed in detail in the examples which follow.

The data capture layer 108 receives the property location information input by the user of the client application 102. The property location information can include, but is not limited to a street address, an APN, geographical coordinates, or other information identifying the location of the property. The data capture layer 108 is an AI driven, parallel processing layer of the property design pipeline 104 that utilizes multiple AI driven module that operate in parallel to rapidly obtain and analyze data from numerous data sources 110 and to create generated property information 135. The data sources 110 can include one or more public and/or private data source that provide information about the property and/or local building regulations.

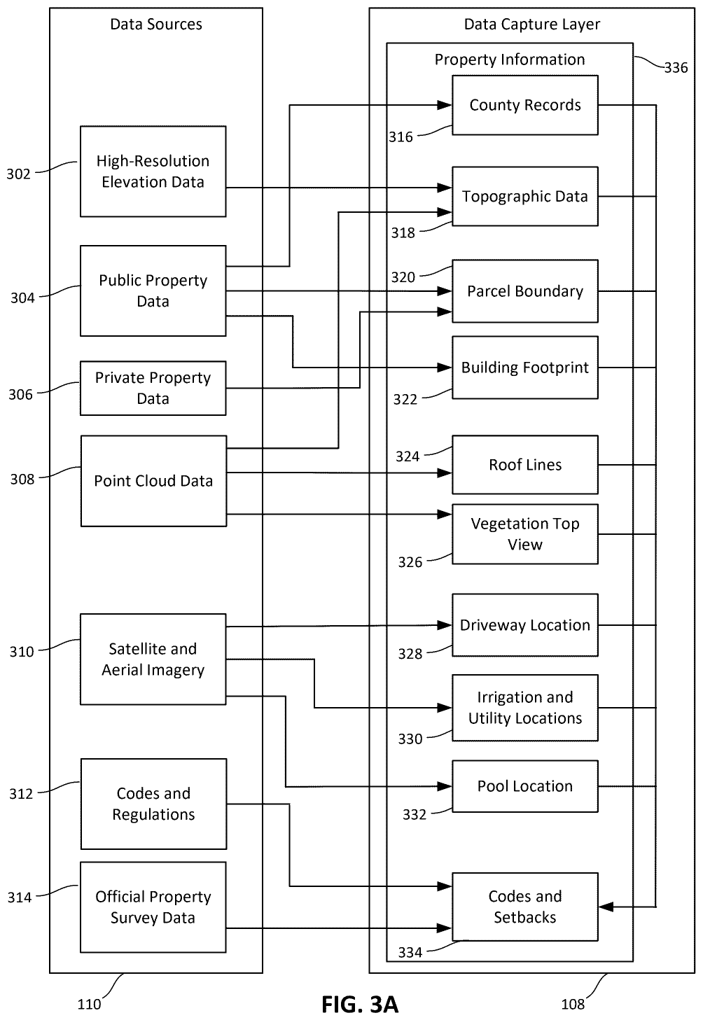

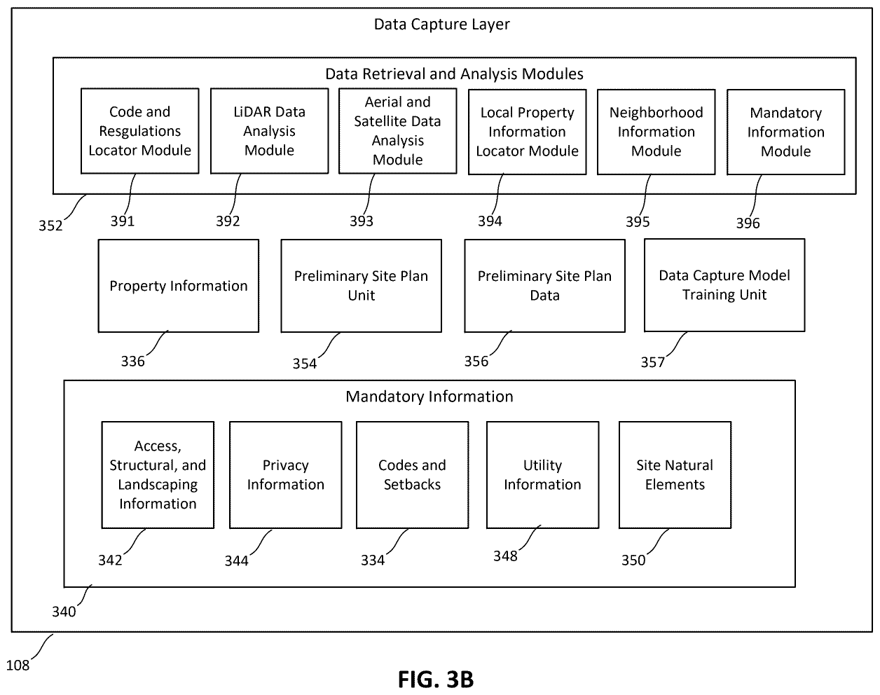

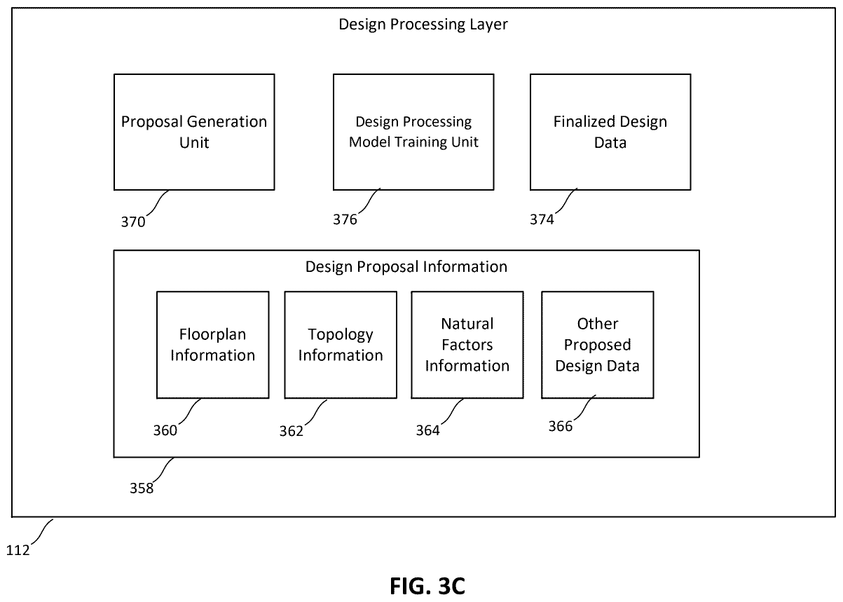

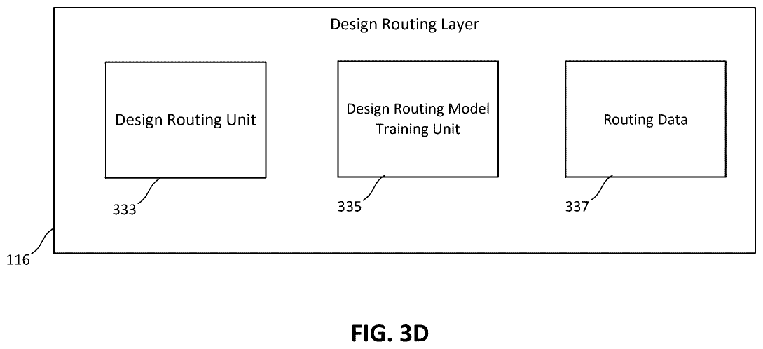

FIG. 3A shows an example of some of the types of data sources that may be utilized and how the parallel AI drive modules of the data capture layer 108 processes information from these data sources to generate various types of information used for creating the project design. The data capture layer 108 collects and analyze the data from the data sources 110 to generate mandatory information that the property design pipeline 104 must consider when generating a proposed design. The mandatory information may include but is not limited to access information, privacy information, regulatory information, utility information, and/or natural elements of the site of the property. Additional details of the mandatory information considered by the data capture layer 108 is discussed with respect to FIG. 3B, which shows an example implementation of the data capture layer 108. The data capture layer 108 generates a preliminary site plan that includes various elements of the property based on the mandatory information. The data capture layer 108 provides this preliminary site plan to the design processing layer 112. The design processing layer 112 analyzes the preliminary site plan customizes the preliminary site plan according to the natural language prompts entered by the user that describe the features of the design project. The features can include structural and/or landscape design features of the construction project. The design processing layer 112 utilizes one or more machine learning models provided by the artificial intelligence services platform 114 to generate a proposed design for the construction project based on the preliminary site plan and the natural language prompts provided by the user. The design processing layer 112 provides the content associated with the preliminary site plan to the client application 102 and causes the client application 102 to present these on a user interface of the client application 102. The user interface also includes an input that enables the user to input natural language prompts that enable the user to request changes to the proposed design. The design processing layer 112 receives these natural language prompts and constructs prompts to one or more of models of the artificial intelligence services platform 114 to revise the proposed design. Once the design has been finalized, the design routing layer 116 generates design content 118 for the project design. The design content 118 can include content such as but not limited to 2D and/or 3D models of the design project, point cloud representations of the design, detailed blueprints, and a detailed cost estimate for the construction project. The design processing layer enables the user to provide feedback on the proposed design via the chat user interface shown in the examples which follow. A technical benefit of this approach is that the user is able to describe in natural language how the user would like to modify a proposed design without the user having an understanding of how these changes would be impacted by local results and regulations, setbacks, utility locations and accessibility, and other factors that constrain the proposed design. The design processing layer 112 analyzes the natural language prompt to understand how the user would like to modify the proposed design, determines the various factors that constrain the proposed design, and modifies the design to satisfy the intent of the user as well as these factors. If an aspect of the modifications proposed by the user cannot be satisfied for various reasons, such as but not limited to code or regulations, setback requirements, or cost, the design processing layer 112 notifies the user of the aspects that could not be satisfied and why these aspects could not be satisfied. The user may then propose further changes to the proposed design via natural language prompts.

In some implementations, the user interface of the client application 102 provides one or more sample images of structural design elements and/or landscape design elements that include examples of the type of design elements and/or style that the user would like to incorporate into the new design project. The user can select these images and provide them with a natural language description of the design project to be created.

The artificial intelligence services platform 114 is implemented by a design platform, such as the design services platform 204 shown in FIG. 2, which implements the property design pipeline 104. In other implementations, at least some of the models implemented by the artificial intelligence services platform 114 are implemented by one or more cloud-based services separate from the design services platform 204, and the design processing layer 112 of the property design pipeline 104 sends queries to the remote cloud-based services and receives content generated by the models by these queries. The artificial intelligence services platform 114 implements one or more generative models that are configured to receive textual natural language prompt as an input and to generate textual content, image content, 2D or 3D plans or models of a design, and/or other content associated with the design project. The models are multimodal models in some implementations, and the model receives a natural language prompt and one or more other types of content as input. Such multimodal models can receive images, photographs, 2D or 3D plans or models of the design, and/or other such types of content. This content can be content that is user provided content, such as images of example structural design elements or landscape design elements provided by the user. The content may also be content that has been previously generated by the multimodal model and is to be revised based on feedback provided by the user.

The design routing layer 116 generates various types of design content 118 once the user has provided an indication that the proposed design is finalized. The design routing layer 116 constructs prompts to the routing black box AI model 218 and/or one or more of the other generative models 220 of the artificial intelligence services platform 114. In some implementations, the design routing layer 116 generates a set of default design content items in response to the user finalizing the design. The user may also specify specific design content items that the user would like to have generated via a natural language prompt. The design content items may include but are not limited to construction estimates, bid documents for builders to bid on the construction project, PDFs other document types of the finalized design, plans for constructing the finalized project, permit applications for the locale in which the property is located including filing in and submitting the required documentation electronically where available, loan document for obtaining financing for the construction project, and/or other documents or content related to the finalized design. A technical benefit of this approach is that the user can request these documents be generated using natural language, and the user does not need to have any specialized knowledge of construction, permitting, financing, etc. in order to generate the documentation required to complete these steps of the construction process.

FIG. 2 is a diagram of an example computing environment in which the property design pipeline shown in FIG. 1 is implemented. The example implementation shown in FIG. 2 includes a client device 202, a design services platform 204, and the data sources 110 and artificial intelligence services platform 114 shown in FIG. 1. These components can communicate with one another over a network 221. While the example implementation shown in FIG. 2 includes a single client device 202, implementations of the design services platform 204 can support multiple client devices.

The design services platform 204 provides a cloud-based design application and/or provides services to support one or more web-enabled native applications on the client device 202. These applications may include but are not limited to design applications, communications platforms, visualization tools, and collaboration tools for collaboratively creating visual representations of information, and other applications for consuming and/or creating electronic content. The client device 202 and the design services platform 204 communicate with each other over the network 221. The network 221 may be a combination of one or more public and/or private networks and may be implemented at least in part by the Internet. The design services platform 204 implements the property design pipeline 104 in the implementation shown in FIG. 2. However, in other implementations, all or a portion of the functionality of the property design pipeline 104 is implemented by the native application 206 of the client device 202.

The client device 202 is a computing device that may be implemented as a portable electronic device, such as a mobile phone, a tablet computer, a laptop computer, a portable digital assistant device, a portable game console, and/or other such devices in some implementations. The client device 202 may also be implemented in computing devices having other form factors, such as a desktop computer, vehicle onboard computing system, a kiosk, a point-of-sale system, a video game console, and/or other types of computing devices in other implementations. While the example implementation illustrated in FIG. 2 includes a single client device 202, other implementations may include a different number of client devices that utilize services provided by the design services platform 204.

The client device 202 includes a native application 206 and a browser application 208. The native application 206 is a web-enabled native application, in some implementations, implements a design application as discussed above. The browser application 208 can be used for accessing and viewing web-based content provided by the design services platform 204. In such implementations, the design services platform 204 implements one or more web applications, such as the web application 210, that implements the functionality of the design application discussed in the preceding examples. The design services platform 204 supports both the native application 206 and a web application 210 in some implementations, and the users may choose which approach best suits their needs.

The artificial intelligence services platform 114 implements generative AI models used to generate content for the property design pipeline 104. The artificial intelligence services platform 114 includes a design capture black box AI model 214, a design processing black box AI model 216, and a routing black box AI model 218, and other generative models 220. The design capture black box AI model 214, the processing black box AI model 216, and the routing black box AI model 218 are generative models that receive natural language prompts and/or other inputs and generate various types of content for proposed designs and/or finalized designs being developed by the property design pipeline 104. The design capture black box AI model 214, the processing black box AI model 216, and the routing black box AI model 218 each provide a Generative Pre-trained Transformer (GPT) style interface that enables the model to receive natural language prompts that have been input by a user that requests that the model perform certain tasks associated with the property design pipeline 104. Examples of such a user interface are provided in FIGS. 4A-4I. The design capture black box AI model 214, the design processing black box AI model 216, and the routing black box AI model 218 can be implemented using a GPT model, such as but not limited to a GPT-3 model, a GPT-4 model, and GPT-4 with Vision (GPT-4V) models. Other generative models, such as a Bidirectional Encoder Representations from Transformers (BERT) model, a Pathways Language Model (PaLM), a Unified Pre-Trained Language Model (UniLM), XLNet, or other such models may be utilized in other implementations. The design capture black box AI model 214, the design processing black box AI model 216, and the routing black box AI model 218 are trained on property-specific and/or user-specific information as discussed in the examples that follow.

The other generative models 220 include one or more generative models that can generate various types of content for the property design pipeline 104 for a proposed design or finalized design. The other generative models 220 can also include text-to-image generative models that are trained to generate imagery from a natural language prompt. The image generating models are multimodal models in some implementations that can receive a natural language prompt and one or more sample images as inputs. The image generative models are used by the property design pipeline 104 to generate preliminary site plans, plans for proposed designs, blueprints, and 2D and/or 3D renderings of the structures and/or landscape elements included in a design. GPT-4V models are used in some implementations to analyze sample images of structural and/or landscape elements provided by the user to extract information from the sample images that can be used to generate a design for a construction project. Other implementations may utilize other models or other generative models to generate textual content in response to user prompts. The generative models can also include text-to-image generative models that are trained to generate imagery from a natural language prompt. The image generating models are multimodal models in some implementations that can receive a natural language prompt and one or more sample images as inputs. The image generative models are used by the property design pipeline 104 to generate preliminary site plans, plans for proposed designs, blueprints, and 2D and/or 3D renderings of the structures and/or landscape elements included in a design.

FIG. 3A is a diagram showing an example implementation of the data sources 110 and the data capture layer 108 of the property design pipeline shown in FIG. 1. In the implementation shown in FIG. 3A, the data sources 110 include high-resolution elevation data 302, public property data 304, private property data 306, point cloud data 308, satellite and aerial imagery 310, codes and regulations data 312, and official property survey data 314. Other data source may be included in other implementations. The data capture layer 108 generates the property information 336 based on data obtained from these various sources. In the example shown in FIG. 3A, the property information 336 includes county records data 316, topographic data 318, parcel boundary data 320, building footprint data 322, roof lines data 324, vegetation top view data 326, driveway location data 328, irrigation equipment locations 330, pool location data 332, and codes and setbacks data 334.

The high-resolution elevation data 302 provides a digital representation of terrain. The data capture layer 108 queries the high-resolution elevation data 302 to obtain terrain information for the property for which a property design is being generated. The terrain information is used by the property design pipeline 104 to determine where structures and/or landscaping may be placed on the property being developed. The terrain information is also used by the property design pipeline 104 to determine whether the grading, sloping, and/or other alterations to the to the terrain may be necessary for a particular proposed design. The terrain information is also used by the property design pipeline 104 to determine which types of foundation and/or other construction techniques would be required to construct a proposed design and/or the types of landscaping elements that would be appropriate for the terrain.

The public property data 304 is obtained from governmental or other publicly accessible data sources that provide free or paid access to information about real property where a property for which a proposed design is being developed. The private property data 306 is obtained from private data sources which may provide free or paid access to such data. The property data may include ownership information, property maps, and/or other such information that can be used to when generating a proposed design. The data capture layer 108 extracts parcel boundary data 320 from the public property data 304 and/or the private property data 306. The parcel boundary data 320 indicates the boundaries of the property for which the design is to be created. The data capture layer 108 can reformat the public property data 304 and/or the private property data 306 to a standard format that can be utilized by the models of the artificial intelligence services platform 114. The data capture layer 108 can also generate county records data 316 from the public property data 304 that includes information for the county, state, region, province, country, or other geographical area in which the property is located. The county records data 316 can include ownership information, tax assessment information, structural information, and/or other information associated with the property. The data capture layer 108 can also generate building footprint data 322 from the public property data 304. The public property data 304 may include site plans and/or blueprints for the property that indicate the location and details of structures and/or other improvements included on the property.

The point cloud data 308 is a set of data points in a 3D coordinate system that provides a 3D representation of the property for which the proposed design is being generated. The point cloud data 308 is captured using lidar, photogrammetry, or other techniques that generate 3D representations that can be modeled as a point cloud. The data capture layer 108 generates topographic data 318 for the property from the high-resolution elevation data 302 and/or the point cloud data 308. The data capture layer 108 analyzes the high-resolution elevation data and the point cloud data 308 and converts the data to standard format so that the data can be combined. The point cloud data 308 and the high-resolution elevation data 302 may include significant amounts of data that are unrelated to the property for which the property design is being generated. The data capture layer 108 selects a portion of the point cloud data 308 and the high-resolution elevation data 302 that includes the property for which the proposed design is being created and may also include at least a portion of neighboring properties. The point cloud data 308 may also include vegetation, structures, and/or other features of the property for which the design is being created. The data capture layer 108 generates roof lines data 324 for structures on the property and/or on neighboring properties. The data capture layer 108 also generates vegetation top view data 326. The vegetation top view data 326 shows the position of existing vegetation that may be incorporated into a proposed design and/or may need to be removed to construct the proposed design.

The satellite and aerial imagery 310 includes images captured using satellites and/or aircraft. The satellite and aerial imagery 310 may be obtained from governmental data sources and/or from private data sources. The data capture layer 108 requests imagery data from the data sources 110 that includes the property for which the design is being developed. The imagery data may include an area that is substantially larger than the property for which the design is being created. The data capture layer 108 selects a portion of the imagery that includes the property for which the proposed design is being created and may also include at least a portion of neighboring properties. The data capture layer 108 analyzes the satellite imagery using one or more machine learning models of the artificial intelligence services platform 114 to extract features of the property. The data capture layer 108 constructs prompts to one or more machine learning models to identify specific features of the property, such as structure locations, driveway location data 328, pool location data 332, the irrigation equipment location data 330, and/or other features of the property. Some properties may not include all of these features.

The codes and regulations data 312 includes building codes and regulations that apply to the area in which the property is located. The data capture unit 108 obtains an electronic copy of these codes and regulations from one or more governmental entities that maintain these electronic copies.

The official property survey data 314 is data obtained from an official survey of the property. The official property survey data 314 is generated from data obtained from a surveyor. The official property survey data 314 includes property boundary and dimension information. The official property survey data 314 can also include information about improvements to the property, such as fences, garages, pools, and/or other structures.

The data capture unit analyzes the codes and regulations data 312 and the official property survey data 314 to generate codes and setback data 334. The setback information indicates the distance that a house or other structure must be from the front, back, and/or side property lines of the property. The property design pipeline 104 utilize this information to determine where structures, pools, and/or other such features may be placed on the property when generating a proposed design.

The example data sources 110 shown in FIG. 3A are not exhaustive. Other implementations may include a different combination of data sources 110 that are utilized by the data capture layer 108. The data capture layer 108 utilizes the information collected from these various sources to generate a preliminary site plan that includes various elements of the property based on the data collected. At least a portion of the data collected is considered mandatory information. The term mandatory information, as used herein, refers to data that the property design pipeline 104 must consider when generating a proposed design for a construction project. The parcel boundary data 320 and the codes and setbacks data 334 are one example of such mandatory information. Additional examples of mandatory information are shown in FIG. 3B. A technical benefit of the techniques herein is that the property design pipeline 104 automatically identifies and retrieves the relevant mandatory information based on the location information input by the user and integrates this information into the proposed designs. The user interacts with the design application via simple chat interface, such that which might be used with chat GPT, which the users are already familiar with and comfortable using.

FIG. 3B is a diagram showing another example implementation of the data capture layer 108 of the property design pipeline 104 shown in the preceding figures. As discussed in the preceding examples, the data capture layer 108 obtains information from the data sources 110 based on the property location and generates a preliminary site plan. The preliminary site plan represents a current state of the property before a proposed design is generated. The preliminary site plan includes information associated with access to the property, existing structures and landscaping, application codes and regulations, existing utility information, and/or other information that represents a current state of the property before construction of the proposed design. An example of a preliminary site plan is provided in FIG. 4D and is discussed in detail in the examples which follow.

The data retrieval and analysis modules 352 access the various data sources of the data sources 110 to generate the property information 336 shown in FIG. 3A. The retrieval and access modules of the data retrieval and analysis modules are AI driven modules that run in parallel to collect and analyze data about the property. A technical benefit of this parallel processing approach is that the property design pipeline 104 can rapidly respond to a user prompt including the location information in a matter of seconds to minutes by generating a preliminary site plan for the property. In contrast, the current approach for developing such a preliminary site plan requires manually collecting and analyzing this information which can take several weeks. In the example implementation shown in FIG. 3B, the data retrieval and analysis modules 352 include a code and regulations locator module 391, a lidar data analysis module 392, an aerial and satellite data analysis module 393, a local property information locator module 394, and a neighborhood information module 395. The code and regulations locator module 391 is searches for and obtains the codes and regulations data 312 and the official property survey data 314 (where available), analyzes the data, and generates the codes and setbacks information 334 for the property. The lidar data analysis module 392 searches for and obtains the point cloud data 308 for the property. The lidar data analysis modules analyzes the point cloud data 308 using one or more AI models to generate the roof lines data 324, the vegetation top view data 326, and/or other data included in the property information 336. The aerial and satellite data analysis module 393 utilizes one or more AI models to search the satellite and aerial imagery 310 associated with the property and to extract a relevant portion of the imagery that includes the property, and to combine the imagery data from multiple sources where multiple aerial and/or satellite images of the property are located. The local property information locator module 394 utilizes one or more AI models to search for public property date 304 and private property data 306 associated with the property and to extract parcel boundary data 320, building footprint data 322, and/or other property information 336 associated with the property. The neighborhood information module 395 is an AI driven module that searches for information about the area in which the property is located and generates various information, such as but not limited to price per square foot for properties in that area, geotechnical information for the property, natural features of the property, and/or surrounding area, and/or other information that may be utilized to assist with the design and cost estimates. The example AI driven modules of the data retrieval and analysis modules 352 discussed herein are merely non-limiting examples of the types of AI driven module that may be implemented by the property design pipeline 104.

The data retrieval and analysis modules 352 extract mandatory information module 340 from the property information 336. The data retrieval and analysis modules 352 include a mandatory information module 396, which is an AI driven module that analyzes the property information 336 and extracts the mandatory information 340. The mandatory information module 340 constructs one or more prompts to a generative language model of the artificial intelligence services platform 114 to cause the model to generate the mandatory data from the property information generated by the other AI driven modules of the data retrieval and analysis modules 352. The mandatory information 340 includes information that the preliminary site plan unit 354 must consider when generating the preliminary site plan. The mandatory information 340 includes information related to access, structural, and landscaping information 342. The access information identifies any roads, driveways, easements, or other means of accessing the property. The structural information identifies and buildings which currently exist on the property. The landscaping information identifies existing landscaping elements which currently exist on the property, including but not limited to vegetation, decks or patios, pergolas, pools, gazebos, greenhouses, and/or other structures not included in the structural information. The preliminary site plan will identify these features of the property, and the design processing layer 112 will attempt to incorporate these features into the proposed design or suggest that such features be modified or removed if necessary.

The mandatory information module 340 also determines privacy information 344 for the property. The privacy information includes an indication whether there are any neighboring properties and/or structures proximate to the property for which the proposed design is to be developed that would be impacted. The privacy information can include walls, fences, vegetation, and/or other features between the property and the neighboring properties and/or structures that may enhance natural features.

The mandatory information module 340 also includes the codes and setbacks information 334 from the property information 336 in the mandatory information 340 used to generate the proposed design.

The mandatory information module 340 also generates utility information 348 for the property based on the property information 336. The utility information can include underground and/or above-ground utilities. The underground utility information can include underground water and/or sewer pipes, underground cables, and/or other utility-related elements that are buried on the property. The above-ground utilities may include above-ground powerlines, telephone lines, fiberoptic lines, and/or cable lines. In some implementations, the mandatory information module 340 utilizes one or more models of the artificial intelligence services platform 114 to analyze data from the property information 336 to identify the location of utilities on the property. For example, the satellite imagery of the property may be analyzed to identify the presence of above-ground cables and/or utility boxes, while county records or other information may be analyzed to obtain information for underground cables and/or pipes.

The mandatory information module 340 also generates site natural elements information 350, which includes vegetation and/or other natural elements of the landscape that are not expressly included in the landscaping information. The natural elements information 350 may identify the presence of water elements, such as but not limited ponds, creeks, or rivers. The natural elements information 350 may also include the presence of large rock features, cliffs or steep grades, and/or other natural elements of the landscape that may impact the proposed design and/or the cost associated with implementing the proposed design.

The data capture model training unit 357 of the data capture layer 108 trains the design capture black box AI model 214 using the property information 336, the mandatory information 340, and/or other information obtained or generated by the data capture layer 108. The data capture model training unit 357 trains the design capture black box AI model 214 which is used to generate at least a portion of the site plan data. This training provides the design capture black box AI model 214 with the information that the models needs to be able to generate the preliminary site plan. As discussed above, the design capture black box AI model 214 is a generative model that provides a chat interface that enables the user to communicate with the model via natural language prompts and/or to process natural language prompts constructed by elements of the data capture layer 108.

The preliminary site plan unit 354 generates the preliminary site plan 354 from the mandatory information 340. The preliminary site plan unit 354 constructs a series of prompts to the design capture black box AI model 214 and/or one or more of the other generative models 220 of the artificial intelligence services platform 114 to cause the models to generate the preliminary site plan data 356. The preliminary site plan unit 354 selects the prompts from a set of prompt templates in some implementations, where each prompt template is customized to request that a particular model perform a particular task. The preliminary site plan unit 354 can modify the template as necessary to generate a prompt to the model. The preliminary site plan unit 354 sends a request to the artificial intelligence services platform 114 to provide the prompt to a specific generative model. The request may also include data from the mandatory information 340 and/or the property information 336 to provide as an input to the model. The generation of the preliminary site plan can be a multistage process in which the preliminary site plan unit 354 constructs multiple prompts for the generative models. In such instances, the intermediate results obtained from generative models in response to prompts may be provided as an input to one or more generative models of the artificial intelligence services platform 114. The preliminary site plan unit 354 outputs preliminary site plan data 356 which may include a 2D rendering of the property with various elements of the property identified. An example of a preliminary site plan is shown in FIG. 4D, which is described in detail in the examples which follow.

FIG. 3C is a diagram showing an example implementation of the design processing layer 112 of the property design pipeline shown in FIG. 1. The design processing layer 112 generates proposed designs based on the natural language prompt input by user in the user interface of the client application 102 and the preliminary site plan output by the data capture layer 108. The design processing layer 112 implements a proposed design based on the preliminary site plan, the property information 336, and/or the mandatory information 340 generated by the data capture layer 108. The design processing layer 112 takes into consideration the natural language prompt input by the user that describes the design that the user has requested be created. The design processing layer 112 generates the design based on what is feasible based on the constraints placed on the design by codes and setbacks 334, the property characteristics, and

The proposal generation unit 370 generates design proposal information 358 for the design proposal. The proposal generation unit 370 implements multiple AI driven modules to generate determining aspects of the design proposal in parallel, much like the data retrieval and analysis modules 352 discussed in the in the previous examples. In a non-limiting example, the proposal generation unit 370 utilizes a first module to determine the user intent for the design based on one or more natural language prompts input by the user that describe the design, a second module to determine what construction is allowed based on the local, state, and/or county codes for the given address, a third module to determine which types of construction would be feasible based on the topography and other characteristics of the property, a fourth module to determine what would be permitted by the user based on the proposed budget, and a fifth module to determine characteristics of the construction being designed (e.g., will the construction require a foundation, will the construction need access to utilities, is the construction being built on an elevation that would require piers to support the structure, and/or other characteristics of the design). Each of the AI driven modules constructs prompts for one or more of the generative models of the generative models of the artificial intelligence services platform 114. These modules operate in parallel with one another to collect and analyze data from the natural language prompts and the preliminary site plan, the property information 336, and/or the mandatory information 340 generated by the data capture layer 108 to generate intermediate design data. Consequently, the property design pipeline 104 can generate the proposed content in much faster than if the design content was generated sequentially or generated manually using current techniques. Furthermore, as content items are completed, these content items can be presented to the user on a user interface of the design application, allowing the user to review the design proposal and providing feedback as soon as possible.

The design processing model training unit 376 of the design processing layer 112 trains the design capture black box AI model 214 using the intermediate design data, and may also include the property information 336, the mandatory information 340, and/or other information obtained or generated by the data capture layer 108 as well as existing design proposal information 358 for designs that are being modified. The design processing model training unit 376 trains the design capture black box AI model 214 which is used to generate at least a portion of the content for the design plan. This training provides the design capture black box AI model 214 with the information that the models needs to be able to generate the design proposal information 358. As discussed above, the design capture black box AI model 214 is a generative model that provides a chat interface that enables the user to communicate with the model via natural language prompts and/or to process natural language prompts constructed by elements of the design processing layer 112. The design capture black box AI model 214 also learns the behavior of the user as the user interacts with the design capture black box AI model 214 via natural language prompts. The design capture black box AI model 214 learns various design preferences of the user and integrates these preferences into the content generated by the design capture black box AI model 214. A technical benefit of this approach is that the inferences of the design capture black box AI model 214 are more likely to satisfy the requirements of the user. Consequently, the user is less likely to request revisions to the design proposals.

In the example implementation shown in FIG. 3C, the design proposal information 358 includes floorplan information 360, topology information 362, natural factors information 364, and other proposed design data 366. Each of these elements of the design proposal data can be generated by one or more AI driven modules of the proposal generation unit 370 operating in parallel as discussed above.

The floorplan information 360 includes floorplans for any structures included in the proposed design and/or plans for any landscaping included in the proposed design. A module of the proposal generation unit 370 constructs prompts for the design processing black box AI model 216, the design capture black box AI model 214, and/or one or more of the other generative models 220 of the artificial intelligence services platform 114 to cause the models to generate the floorplans for the structures and/or the plans for the landscaping. The prompts constructed by the proposal generation unit 370 include the natural language prompt or prompts from the user describing the desired design for the construction project. The prompts also include the codes and setback information 334 in some implementations to ensure that the plans generated comply with the codes and setback information 334. The prompts also include the preliminary site plan, which provides context regarding the property that the models can use when generating content for the proposed design.

A module of the proposal generation unit 370 constructs prompts for the design processing black box AI model 216, the design capture black box AI model 214, and/or one or more of the other generative models 220 of the artificial intelligence services platform 114 to cause the models to generate the topology information 362. The topology information includes structural information that includes the spatial arrangement of structural members of the structures and/or landscape features included in the proposed design. The topological information can be used to generate detailed construction plans for these structures and/or landscape features. The topology information may also include information for grading, sloping, and/or other alterations to the to the terrain may be necessary to construct the proposed design.

A module of the proposal generation unit 370 also constructs prompts for the design processing black box AI model 216, the design capture black box AI model 214, and/or one or more of the other generative models 220 of the artificial intelligence services platform 114 to cause the models to generate the natural factors information 364. The natural factors information 364 includes natural factors, such as but not limited to sun orientation information, wind speed and direction information, and/or other information related to natural factors that may impact the proposed design.

The generation of the preliminary site proposed design can be a multistage process in which modules of the proposal generation unit 370 constructs multiple prompts for the generative models. In such instances, the intermediate results obtained from generative models in response to prompts may be provided as an input to one or more generative models of the artificial intelligence services platform 114 to generate additional content for the proposed design. The preliminary site plan unit 354 outputs preliminary site plan data 356 which may include a 2D rendering of the property with various elements of the property identified. An example of a proposed design is shown in FIGS. 4E-4H, which is described in detail in the examples which follow.

FIG. 3D is a diagram showing an example implementation of the design routing layer 116 of the property design pipeline 104. The design routing unit 333 of the design routing layer 116 generates various types of design content 118 once the user has provided an indication that the proposed design is finalized. The design routing unit 333 constructs prompts to the routing black box AI model 218 and/or one or more of the other generative models 220 of the artificial intelligence services platform 114 to generate various design content items for a finalized design. In some implementations, the design routing unit 333 generates a set of default design content items in response to the user finalizing the design. The user may also specify specific design content items that the user would like to have generated via a natural language prompt. The design content items may include but are not limited to construction estimates, bid documents for builders to bid on the construction project, PDFs other document types of the finalized design, plans for constructing the finalized project, permit applications for the locale in which the property is located including filing in and submitting the required documentation electronically where available, loan document for obtaining financing for the construction project, and/or other documents or content related to the finalized design. A technical benefit of this approach is that the user can request these documents be generated using natural language, and the user does not need to have any specialized knowledge of construction, permitting, financing, etc. in order to generate the documentation required to complete these steps of the construction process.

The design routing model training unit 335 of the design routing layer 116 trains the routing black box AI model 218 using information obtained or generated by the data capture layer 108 and the design processing layer 112 as well as the routing data 337. The design routing model training unit 335 trains the routing black box AI model 218 which is used to generate at least a portion of the design content items discussed above. The routing black box AI model 218 also learns the behavior of the user as the user interacts with the routing black box AI model 218 via natural language prompts. The routing black box AI model 218 learns the type and attributes of content items typically generated by the user and integrates these preferences into the content generated by the routing black box AI model 218. A technical benefit of this approach is that the inferences of the routing black box AI model 218 are more likely to satisfy the requirements of the user. Consequently, the user is less likely to request revisions to the content items generated for the project.

FIGS. 4A-4I are diagrams showing an example user interface 400 of a design application according to the techniques disclosed herein. The user interface 400 enables a user to create a new project design or to revise an existing project design. The user interface 400 can be implemented by the client application 102 shown in FIG. 1, the native application 206 of the client device 202, or the web application 210 of the design services platform 204.

FIG. 4A shows an example of the user interface 400 of the client application 102. As discussed in the preceding examples, the client application 102 is implemented by the native application 206 of the client device 202 or the web application 210 of the design services platform 204 in some implementations. The user interface 400 in FIG. 4A enables a user to create a new project design. The user can enter the address of the property in the property address field 402 or the APN associated with the address in the APN field 404. The user can then input a natural language description of the project design for a construction project in the prompt field 410. The project can be a residential project, commercial project, or a construction project for a public space. The project may include structural elements, landscape elements, or both. The user can provide a detailed description of the features of these elements, the style of the elements, the desired budget for the project, and/or other features of the construction project. Once the user has input the property location information and the natural language prompt, the user can click on or otherwise activate the control 408 to cause the client application 102 to provide the property location information and the natural language prompt to the property design pipeline 104. In other implementations, the user instructs the client application 102 to create the new design by inputting a natural language prompt. Furthermore. some implementations of the user interface 400 include an option that enables the user to include one or more sample images of structural design elements and/or landscape design elements that include examples of the type of design elements and/or style that the user would like to incorporate into the new design project.

FIG. 4B shows another example of the user interface 400 which also includes a design suggestions pane 412 that includes design suggestions that the user may wish to incorporate into their design. The user may click on or otherwise activate one or more of the design suggestions to add these to these suggestions to the natural language prompt input by the user. The selections that are presented to the user are selected by the property design pipeline 104. In some implementations, the user input unit 106 analyzes the natural language prompt input by the user in the prompt field 410 to determine which design suggestions to present. The user input unit 106 provides the natural language prompt to a language model of the artificial intelligence services platform 114 for analysis in some implementations to obtain the design suggestions. In other implementations, the user input unit 106 selects design selections based on the type of design project (e.g., residential, commercial, or public), whether the natural language prompt indicates that the design includes structures, landscaping, or both. The user input unit 106 also selects the design selection based on keywords included in the natural language prompt in some implementations.

FIG. 4C shows an example of the user interface 400 after the user has input the property location and natural language prompt and requested that the design be created. The user input unit 106 provides the property location information to the data capture layer 108, and the data capture layer 108 obtains and analyzes data from a plurality of data sources, such as the data sources 110. The data capture layer 108 obtains an aerial or satellite photograph of the property specified in the property location information and presents an image of the property to the user to confirm that the property design pipeline 104 has identified the correct property based on the user input. The user can click on or otherwise activate the control 414 to go back to the previous screen to modify their inputs or click on or otherwise activate the control 416 to proceed with the design. In the event that the data capture layer 108 is unable to locate the property based on the property information input by the user, the data capture layer 108 notifies the client application 102 that the property could not be located and causes user input fields to be presented as shown in FIG. 4A with a message indicating that the property could not be located and to correct the property location information.

FIG. 4D shows an example of the user interface 400 presenting a preliminary site plan of the property. The preliminary site plan provides a representation of the current state of the property and may include shading, colorization, and/or other indicators identify various elements of the property, such as property boundaries, structures, pools, landscaping features, driveways, roads, and/or other means of accessing the property. In some implementations, the presentation of the preliminary site plan of the property is optional, and the property design pipeline 104 proceeds to generate and present the proposed design as shown in FIGS. 4E-4I.

FIG. 4E shows an example of the user interface 400 in which the property design pipeline 104 has generated the proposed design and is presenting a proposed site plan 420 for the project. The proposed design includes structural and/or landscaping elements requested by the user in the natural language prompt. The user interface 400 includes prompts that request the user to input any changes that they would like to the structures in the proposed design in the prompt field 424 and to input any changes that they would like to make to the landscaping in the prompt field 426. The natural language prompts input in the prompt field 424 and/or the prompt field 426 are provided by the client application 102 to the property design pipeline 104 for processing, and the design processing layer 112 constructs prompts to one or more models of the artificial intelligence services platform 114 to cause the models to generate a revised version of the proposed design that reflects the changes requested by the user. The revised version of the proposed design is presented to the user on the user interface 400 in response to each prompt. The revision process may be an iterative process in which the user provides prompts to further revise the proposed design until the user is satisfied with the proposed design. The user can then click on or otherwise activate the control 428 to cause the property design pipeline 104 to generate a finalized design from the proposed design.

FIG. 4F shows an example of the user interface 400 in which the finalized design is presented to the user. The user can click on or otherwise activate the control 430 to continue revising the design as shown in FIG. 4E. The user can click on or otherwise activate the control 432 to cause the property design pipeline 104 to finalize the design. In the example shown in FIG. 4F, the design routing layer 116 of the property design pipeline 104 generates the design content 118 for the design project. The design content 118 can include content such as but not limited to 2D and/or 3D models of the design project, point cloud representations of the design, detailed blueprints, and a detailed cost estimate for the construction project.

FIG. 4G shows an example of the user interface 400 in which plans and renderings associated with the finalized design are presented. The user can click on or otherwise activate the control 434 to continue revising the design as shown in FIG. 4E or to click on or otherwise activate the control 436 to finalize the design. FIG. 4H shows another implementation of the user interface 400 which includes a prompt input in which the user can provide a natural language prompt requesting that the property design pipeline 104 generate specified content. The non-limiting example, the user can request that the plans be generated in a particular file format and renderings be generated in another file format. FIG. 4I shows an example of the user interface 400 that presents the details of a finalized design project and the associated content items that the user requested be generated for the design project.

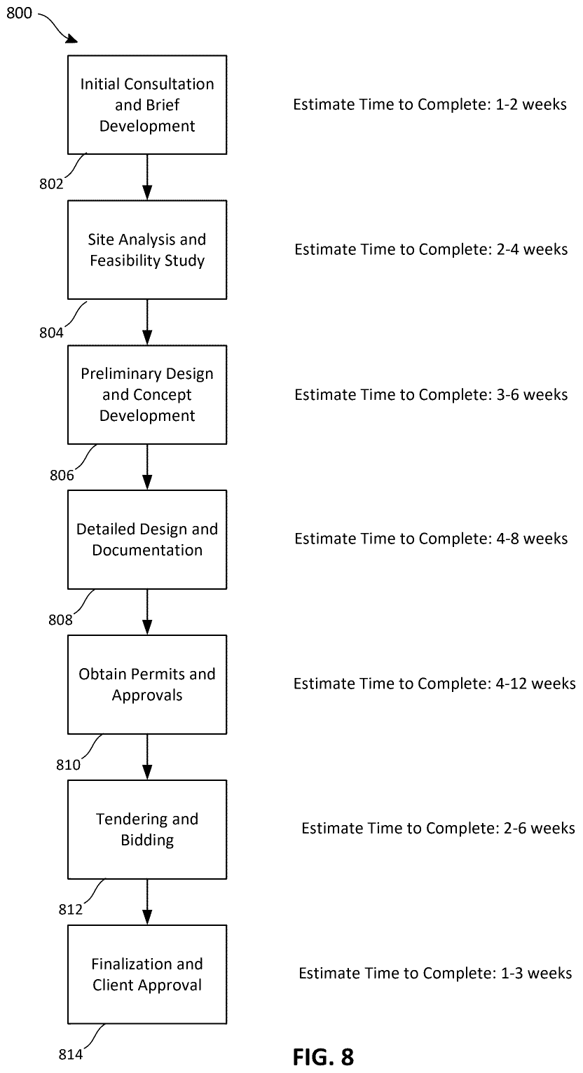

FIG. 8 is a flow diagram of an example of a property design process 800 shows the current approach to property design. FIG. 8 includes estimates for how long each of the stages of the process typically takes. The techniques herein can substantially reduce the time required to create a property design from weeks or months to a matter of minutes or hours using the property design pipeline 104.

The process 800 includes a stage 802 of initial consultation and brief development. This stage involves meetings between the client and the design team to discuss project goals, requirements, budget, and timeline. The design team gathers information gathers information about the client's needs, preferences, and site-specific conditions. This stage typically takes 1 or 2 weeks. The user input unit 106 of the property design pipeline 104 automates the process of gathering information from the client. The client provides a description of the project in one or more natural language prompts that are analyzed by the property design pipeline 104. The property design pipeline 104 can also prompt the user for additional details and/or provide suggestions that can help improve the design for the construction project. The property design pipeline 104 can reduce this stage from a matter of weeks to a matter of minutes to gather the information needed to generate the design from the client.

The process 800 includes a stage 804 of site analysis and feasibility study. The design team conducts a detailed analysis of the site, including its topography, climate, soil conditions, existing structures, and local regulations. The design team assesses the feasibility of the proposed project on the site, identifying any potential issues or constraints that might impact the design. This stage provides a thorough understanding of site constraints and opportunities but is time consuming and expensive because it relies heavily on the expertise of the professionals involved. This stage typically takes 2 to 4 weeks. The property design pipeline 104 automatically obtains data from various data sources 110 that is provided to one or more generative models to create a preliminary site plan for the property. The property design pipeline 104 can reduces this step to a matter of minutes or hours from the several weeks timeframe that would typically be required.

The process 800 includes a stage 806 of preliminary design and concept development. The design team develops initial design concepts based on the project brief and site analysis. These concepts are usually presented to the client in the form of sketches, drawings, or 3D models. The client provides feedback, and the design is refined through several iterations until a preferred concept is agreed upon. While the client can provide feedback during this stage, the iterative process can be lengthy and risks going off-track if not well managed. This stage typically takes 3 to 6 weeks. The design processing layer 112 of the property design pipeline 104 generates the proposed designs for the project based on the natural language prompts input by the user and the preliminary site plan. The user can provide feedback requesting revisions to the proposed designs via natural language prompts. A technical benefit of this approach is that the user can view the revised design in a matter of minutes and provide immediate feedback on the revised design. Consequently, the computing-resource required to generate the plans may be significantly reduced. The revisions do not need to be provided to designers to make manual changes to the design which can result in miscommunications and additional rounds of revisions to the electronic design documents.

The process 800 includes a stage 808 of detailed design and documentation. Once a concept is approved, the design team develops detailed drawings and specifications. These documents include architectural, structural, mechanical, electrical, and plumbing plans, as well as material specifications. This step is crucial for obtaining accurate construction bids and permits. However, this stage is labor intensive and requires significant time to prepare detailed drawings and specifications. This stage typically takes 4 to 8 weeks. The property design pipeline 104 generates the detailed drawings and specifications automatically once the user has approved the proposed design. The property design pipeline 104 constructs prompts for one or more generative models to generate the designs in a matter of minutes rather than the multi-week process in which human designers manually generate such content.

The process 800 includes a stage 810 of obtaining permits and approvals. The necessary documentation is submitted to local authorities for review and approval. This may include zoning approvals, building permits, and environmental clearances. The time taken in this step varies based on local regulations and the complexity of the project. This stage ensures compliance with local regulations necessary for construction but can be a slow process that depends on external agencies. This stage typically takes 4 to 12 weeks.

The process 800 includes a stage 812 of a tendering or bidding process. The detailed design documents are used to solicit bids from contractors. This may be an open bid process or invitations sent to selected contractors. The bids are evaluated based on cost, experience, timeline, and quality of work. A contractor is then selected to carry out the construction work. This stage is time consuming and has the potential for receiving low quality bids. This stage typically takes 4 to 12 weeks. The property design pipeline 104 can facilitate the tendering and bidding process by providing the user with accurate estimates for the cost of construction for a design. Consequently, the efficiency of the tendering and bidding process may be improved.

The process 800 includes a stage 814 of finalization and client approval. In this stage, the final design, along with the chosen contractor and project cost, is presented to the client for approval. Any last-minute changes or adjustments are made during this phase. Once the client gives their approval, the project moves into the construction phase. This stage typically takes 1 to 3 weeks.

The total estimated time to complete the design process is approximately 12 to 24 weeks. The total estimated cost for manual construction design & architecture varies, small projects could be $6,000 to $10,000 while larger projects could exceed $30,000 of cost. This is for design only, at times 3rd party licensed professionals are required such as structural engineers, civil engineers, and/or others, which could double the initial cost and also increase the time to develop the project. The techniques herein can significantly decrease the costs associated with the design process by using generative models to generate much of the design content.

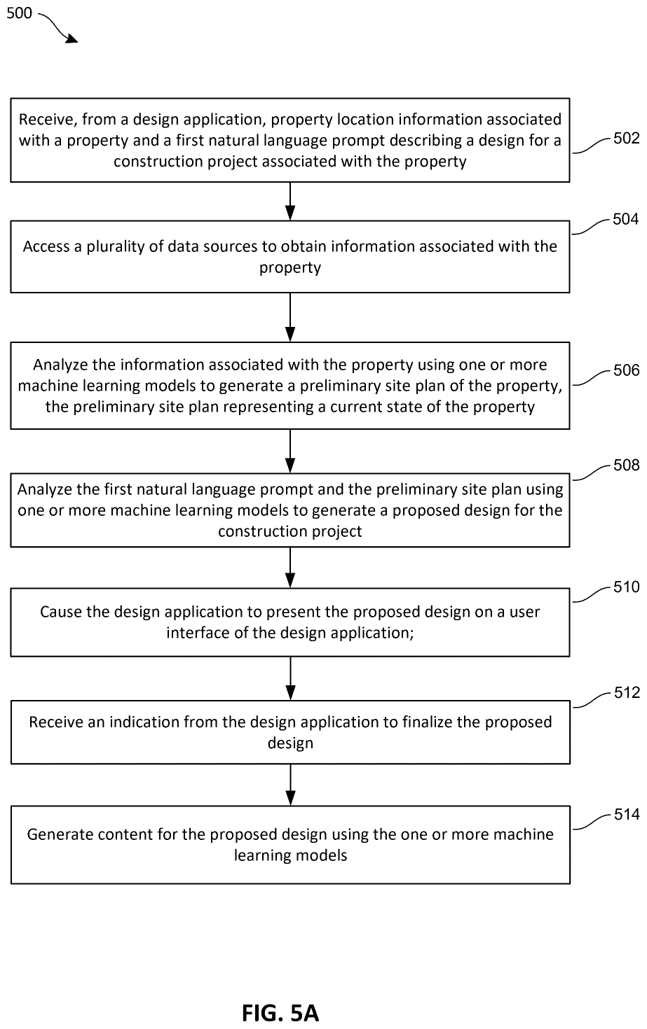

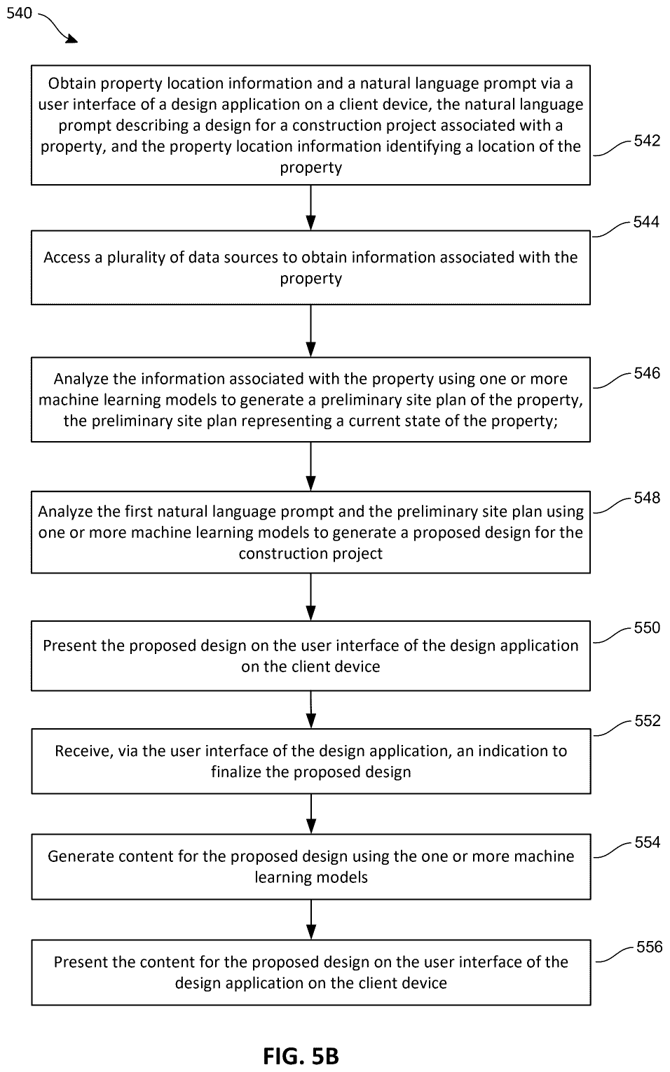

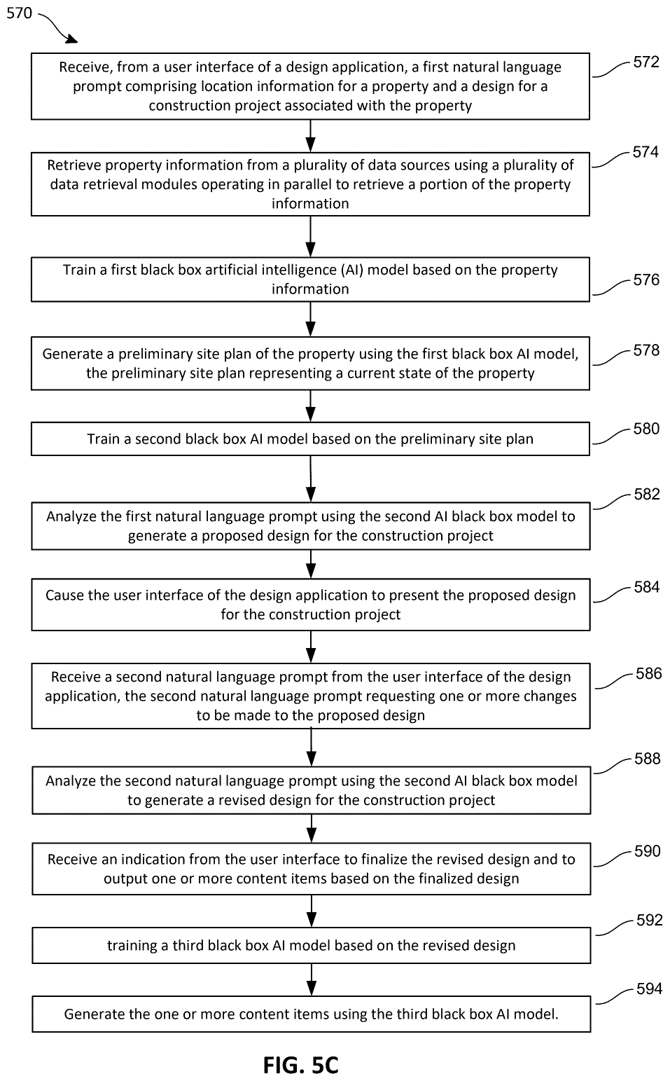

FIG. 5A is a flow chart of another example process 500 for automatically generating a property design according to the techniques disclosed herein. The process 500 can be implemented by the property design pipeline 104 as discussed in the preceding examples.

The process 500 includes an operation 502 of receiving, from a design application, property location information associated with a property and a first natural language prompt describing a design for a construction project associated with the property. As discussed in the preceding examples, the client application 102 can implement the user interface 400 shown in FIG. 4A which enables the user to input a property address or APN. The user input unit 106 receives this information from the client application 102.

The process 500 includes an operation 504 of accessing a plurality of data sources to obtain information associated with the property. The data capture layer 108 analyzes the property information and obtains data from one or more data sources 110.

The process 500 includes an operation 506 of analyzing the information associated with the property using one or more machine learning models to generate a preliminary site plan of the property. The preliminary site plan represents a current state of the property. The data capture layer 108 generates the preliminary site plan from the data obtained from the data sources 110.

The process 500 includes an operation 508 of analyzing the first natural language prompt and the preliminary site plan using one or more machine learning models to generate a proposed design for the construction project. The design processing layer 112 of the property design pipeline 104 generates the proposed design from the preliminary site plan and the natural language prompt.

The process 500 includes an operation 510 of causing the design application to present the proposed design on a user interface 400 of the design application. Examples of the user interface 400 are shown in at least FIGS. 4B-4G.

The process 500 includes an operation 512 of receiving an indication from the design application to finalize the proposed design. The user may click on otherwise activate a control on the user interface 400 of the client application 102 or input a natural language prompt to finalize the proposed design.

The process 500 includes an operation 514 of generating content for the proposed design using the one or more machine learning models. The design routing layer 116 of the property design pipeline 104 generates the design content 118. The design content can be generated in response to a natural language query input by the user via the user interface 400 of the client application 102.

FIG. 5B is a flow chart of another example process 540 for automatically generating a property design according to the techniques disclosed herein. The process 540 can be implemented by the property design pipeline 104 as discussed in the preceding examples.

The process 540 includes an operation 542 of obtaining property location information and a natural language prompt via a user interface of a design application on a client device. The natural language prompt describing a design for a construction project associated with a property, and the property location information identifies a location of the property. As discussed in the preceding examples, the client application 102 can implement the user interface 400 shown in FIG. 4A which enables the user to input a property address or APN. The user input unit 106 receives this information from the client application 102.

The process 540 includes an operation 544 of accessing a plurality of data sources to obtain information associated with the property. The data capture layer 108 analyzes the property information and obtains data from one or more data sources 110.

The process 540 includes an operation 546 of analyzing the information associated with the property using one or more machine learning models to generate a preliminary site plan of the property, the preliminary site plan representing a current state of the property. The design processing layer 112 of the property design pipeline 104 generates the proposed design from the preliminary site plan and the natural language prompt.

The process 540 includes an operation 548 of analyzing the first natural language prompt and the preliminary site plan using one or more machine learning models to generate a proposed design for the construction project. The design processing layer 112 of the property design pipeline 104 generates the proposed design from the preliminary site plan and the natural language prompt.

The process 540 includes an operation 550 of presenting the proposed design on the user interface 400 of the design application on the client device. Examples of the user interface 400 are shown in at least FIGS. 4B-4G.

The process 540 includes an operation 552 of receiving, via the user interface of the design application, an indication to finalize the proposed design. The user may click on otherwise activate a control on the user interface 400 of the client application 102 or input a natural language prompt to finalize the proposed design.

The process 540 includes an operation 554 of generating content for the proposed design using the one or more machine learning models. The design routing layer 116 of the property design pipeline 104 generates the design content 118. The design content can be generated in response to a natural language query input by the user via the user interface 400 of the client application 102.

The process 540 includes an operation 546 of presenting the content for the proposed design on the user interface of the design application on the client device. Examples of the user interface 400 are shown in at least FIG. 4H.

FIG. 5C is a flow chart of another example process 570 for automatically generating a property design according to the techniques disclosed herein. The process 540 can be implemented by the property design pipeline 104 as discussed in the preceding examples.

The process 570 includes an operation 572 of receiving, from a user interface of a design application, a first natural language prompt comprising location information for a property and a design for a construction project associated with the property. The natural language prompt describing a design for a construction project associated with a property, and the property location information identifies a location of the property. As discussed in the preceding examples, the client application 102 can implement the user interface 400 shown in FIG. 4A which enables the user to input a property address or APN. The user input unit 106 receives this information from the client application 102.

The process 570 includes an operation 574 of retrieving property information from a plurality of data sources using a plurality of data retrieval modules operating in parallel to retrieve a portion of the property information. The data capture layer 108 analyzes the property information and obtains data from one or more data sources 110.

The process 570 includes an operation 576 of training a first black box artificial intelligence (AI) model based on the property information. The data capture model training unit 357 trains the data capture black box model 214 based on the property information collected by the data capture layer 108.

The process 570 includes an operation 578 of generating a preliminary site plan of the property using the first black box AI model, the preliminary site plan representing a current state of the property. The preliminary site plan unit 354 constructs prompts for the data capture black box model 214 to generate the preliminary site plan.

The process 570 includes an operation 580 of training a second black box AI model based on the preliminary site plan. The design processing model training unit 376 trains the design processing black box AI model 216 as discussed in the preceding examples.

The process 570 includes an operation 582 of analyzing the first natural language prompt using the second AI black box model to generate a proposed design for the construction project. The proposal generation unit 370 constructs one or more prompts for the design processing black box AI model 216 that causes the model to generate content for the proposed design. The proposal generation unit 370 may also provide prompts to one or more of the other generative models 220 to generate at least a portion of the content.

The process 570 includes an operation 584 of causing the user interface of the design application to present the proposed design for the construction project. The user interface 400 of the design application presents the proposed design to the user. The proposed design may include plans, renderings, and/or other content that presents the proposed design to the user.

The process 570 includes an operation 586 of receiving a second natural language prompt from the user interface of the design application, the second natural language prompt requesting one or more changes to be made to the proposed design. The user can provide one or more natural language prompts that describe revisions that the user would like to make to the proposed design.

The process 570 includes an operation 588 of analyzing the second natural language prompt using the second AI black box model to generate a revised design for the construction project. The design processing layer 112 analyzes the natural language prompt with the revisions using the design processing black box AI model 216 to generate a revised design.

The process 570 includes an operation 590 of receiving an indication from the user interface to finalize the revised design and to output one or more content items based on the finalized design. The user can input a natural language prompt or click on otherwise activate a control on the user interface 400 that indicates that the user approves the revised design and that the design should be finalized.

The process 570 includes an operation 592 of training a third black box AI model based on the revised design and an operation 594 of generating the one or more content items using the third black box AI model. As discussed in the preceding examples, the design routing layer 116 generates the content items specified by the user in the natural language query input in the prompt field of the user interface 400.

The detailed examples of systems, devices, and techniques described in connection with FIGS. 1-5C and 8 are presented herein for illustration of the disclosure and its benefits. Such examples of use should not be construed to be limitations on the logical process embodiments of the disclosure, nor should variations of user interface methods from those described herein be considered outside the scope of the present disclosure. It is understood that references to displaying or presenting an item (such as, but not limited to, presenting an image on a display device, presenting audio via one or more loudspeakers, and/or vibrating a device) include issuing instructions, commands, and/or signals causing, or reasonably expected to cause, a device or system to display or present the item. In some embodiments, various features described in FIGS. 1-5C and 8 are implemented in respective modules, which may also be referred to as, and/or include, logic, components, units, and/or mechanisms. Modules may constitute either software modules (for example, code embodied on a machine-readable medium) or hardware modules.

In some examples, a hardware module may be implemented mechanically, electronically, or with any suitable combination thereof. For example, a hardware module may include dedicated circuitry or logic that is configured to perform certain operations. For example, a hardware module may include a special-purpose processor, such as a field-programmable gate array (FPGA) or an Application Specific Integrated Circuit (ASIC). A hardware module may also include programmable logic or circuitry that is temporarily configured by software to perform certain operations and may include a portion of machine-readable medium data and/or instructions for such configuration. For example, a hardware module may include software encompassed within a programmable processor configured to execute a set of software instructions. It will be appreciated that the decision to implement a hardware module mechanically, in dedicated and permanently configured circuitry, or in temporarily configured circuitry (for example, configured by software) may be driven by cost, time, support, and engineering considerations.

Accordingly, the phrase “hardware module” should be understood to encompass a tangible entity capable of performing certain operations and may be configured or arranged in a certain physical manner, be that an entity that is physically constructed, permanently configured (for example, hardwired), and/or temporarily configured (for example, programmed) to operate in a certain manner or to perform certain operations described herein. As used herein, “hardware-implemented module” refers to a hardware module. Considering examples in which hardware modules are temporarily configured (for example, programmed), each of the hardware modules need not be configured or instantiated at any one instance in time. For example, where a hardware module includes a programmable processor configured by software to become a special-purpose processor, the programmable processor may be configured as respectively different special-purpose processors (for example, including different hardware modules) at different times. Software may accordingly configure a processor or processors, for example, to constitute a particular hardware module at one instance of time and to constitute a different hardware module at a different instance of time. A hardware module implemented using one or more processors may be referred to as being “processor implemented” or “computer implemented.”

Hardware modules can provide information to, and receive information from, other hardware modules. Accordingly, the described hardware modules may be regarded as being communicatively coupled. Where multiple hardware modules exist contemporaneously, communications may be achieved through signal transmission (for example, over appropriate circuits and buses) between or among two or more of the hardware modules. In embodiments in which multiple hardware modules are configured or instantiated at different times, communications between such hardware modules may be achieved, for example, through the storage and retrieval of information in memory devices to which the multiple hardware modules have access. For example, one hardware module may perform an operation and store the output in a memory device, and another hardware module may then access the memory device to retrieve and process the stored output.

In some examples, at least some of the operations of a method may be performed by one or more processors or processor-implemented modules. Moreover, the one or more processors may also operate to support performance of the relevant operations in a “cloud computing” environment or as a “software as a service” (SaaS). For example, at least some of the operations may be performed by, and/or among, multiple computers (as examples of machines including processors), with these operations being accessible via a network (for example, the Internet) and/or via one or more software interfaces (for example, an application program interface (API)). The performance of certain of the operations may be distributed among the processors, not only residing within a single machine, but deployed across several machines. Processors or processor-implemented modules may be in a single geographic location (for example, within a home or office environment, or a server farm), or may be distributed across multiple geographic locations.

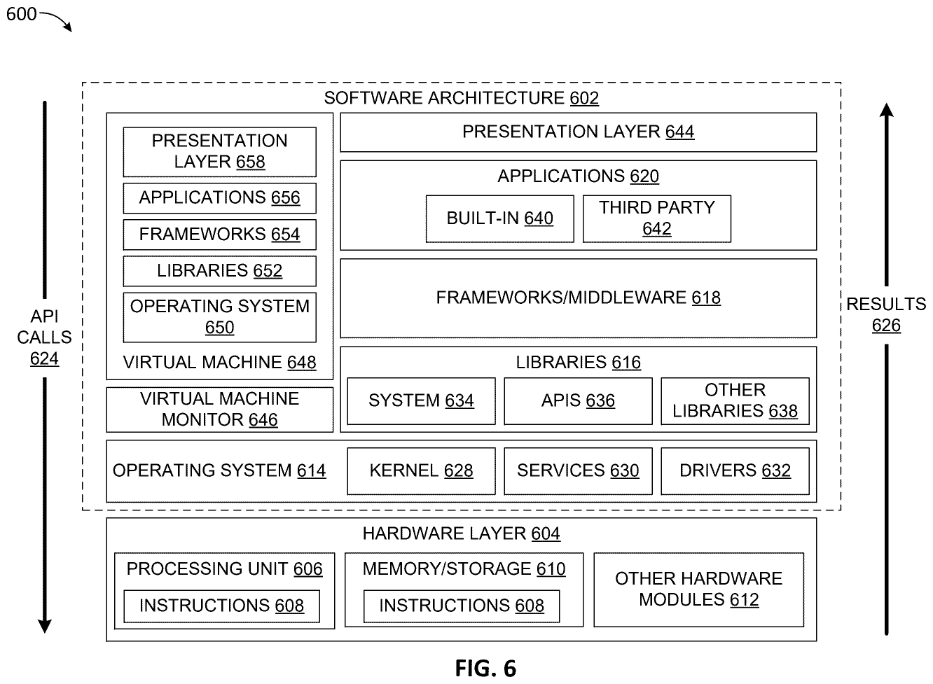

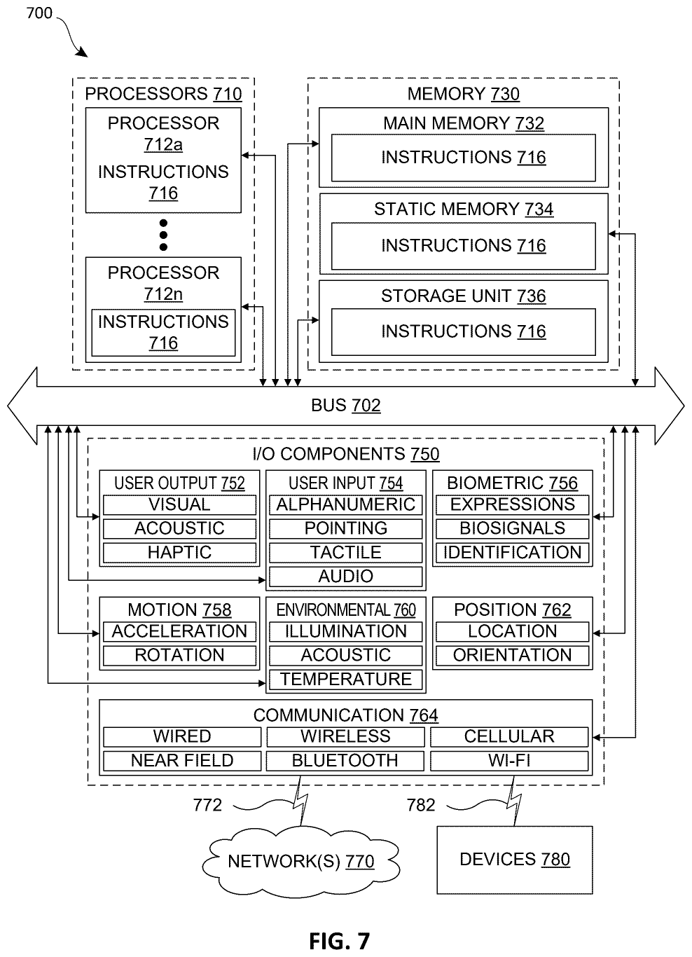

FIG. 6 is a block diagram 600 illustrating an example software architecture 602, various portions of which may be used in conjunction with various hardware architectures herein described, which may implement any of the above-described features. FIG. 6 is a non-limiting example of a software architecture, and it will be appreciated that many other architectures may be implemented to facilitate the functionality described herein. The software architecture 602 may execute on hardware such as a machine 700 of FIG. 7 that includes, among other things, processors 710, memory 730, and input/output (I/O) components 750. A representative hardware layer 604 is illustrated and can represent, for example, the machine 700 of FIG. 7. The representative hardware layer 604 includes a processing unit 606 and associated executable instructions 608. The executable instructions 608 represent executable instructions of the software architecture 602, including implementation of the methods, modules and so forth described herein. The hardware layer 604 also includes a memory/storage 610, which also includes the executable instructions 608 and accompanying data. The hardware layer 604 may also include other hardware modules 612. Instructions 608 held by processing unit 606 may be portions of instructions 608 held by the memory/storage 610.

The example software architecture 602 may be conceptualized as layers, each providing various functionality. For example, the software architecture 602 may include layers and components such as an operating system (OS) 614, libraries 616, frameworks 618, applications 620, and a presentation layer 644. Operationally, the applications 620 and/or other components within the layers may invoke API calls 624 to other layers and receive corresponding results 626. The layers illustrated are representative in nature and other software architectures may include additional or different layers. For example, some mobile or special purpose operating systems may not provide the frameworks/middleware 618.

The OS 614 may manage hardware resources and provide common services. The OS 614 may include, for example, a kernel 628, services 630, and drivers 632. The kernel 628 may act as an abstraction layer between the hardware layer 604 and other software layers. For example, the kernel 628 may be responsible for memory management, processor management (for example, scheduling), component management, networking, security settings, and so on. The services 630 may provide other common services for the other software layers. The drivers 632 may be responsible for controlling or interfacing with the underlying hardware layer 604. For instance, the drivers 632 may include display drivers, camera drivers, memory/storage drivers, peripheral device drivers (for example, via Universal Serial Bus (USB)), network and/or wireless communication drivers, audio drivers, and so forth depending on the hardware and/or software configuration.

The libraries 616 may provide a common infrastructure that may be used by the applications 620 and/or other components and/or layers. The libraries 616 typically provide functionality for use by other software modules to perform tasks, rather than interacting directly with the OS 614. The libraries 616 may include system libraries 634 (for example, C standard library) that may provide functions such as memory allocation, string manipulation, file operations. In addition, the libraries 616 may include API libraries 636 such as media libraries (for example, supporting presentation and manipulation of image, sound, and/or video data formats), graphics libraries (for example, an OpenGL library for rendering 2D and 3D graphics on a display), database libraries (for example, SQLite or other relational database functions), and web libraries (for example, WebKit that may provide web browsing functionality). The libraries 616 may also include a wide variety of other libraries 638 to provide many functions for applications 620 and other software modules.

The frameworks 618 (also sometimes referred to as middleware) provide a higher-level common infrastructure that may be used by the applications 620 and/or other software modules. For example, the frameworks 618 may provide various graphic user interface (GUI) functions, high-level resource management, or high-level location services. The frameworks 618 may provide a broad spectrum of other APIs for applications 620 and/or other software modules.

The applications 620 include built-in applications 640 and/or third-party applications 642. Examples of built-in applications 640 may include, but are not limited to, a contacts application, a browser application, a location application, a media application, a messaging application, and/or a game application. Third-party applications 642 may include any applications developed by an entity other than the vendor of the particular platform. The applications 620 may use functions available via OS 614, libraries 616, frameworks 618, and presentation layer 644 to create user interfaces to interact with users.

Some software architectures use virtual machines, as illustrated by a virtual machine 648. The virtual machine 648 provides an execution environment where applications/modules can execute as if they were executing on a hardware machine (such as the machine 700 of FIG. 7, for example). The virtual machine 648 may be hosted by a host OS (for example, OS 614) or hypervisor, and may have a virtual machine monitor 646 which manages operation of the virtual machine 648 and interoperation with the host operating system. A software architecture, which may be different from software architecture 602 outside of the virtual machine, executes within the virtual machine 648 such as an OS 650, libraries 652, frameworks 654, applications 656, and/or a presentation layer 658.

FIG. 7 is a block diagram illustrating components of an example machine 700 configured to read instructions from a machine-readable medium (for example, a machine-readable storage medium) and perform any of the features described herein. The example machine 700 is in a form of a computer system, within which instructions 716 (for example, in the form of software components) for causing the machine 700 to perform any of the features described herein may be executed. As such, the instructions 716 may be used to implement modules or components described herein. The instructions 716 cause unprogrammed and/or unconfigured machine 700 to operate as a particular machine configured to carry out the described features. The machine 700 may be configured to operate as a standalone device or may be coupled (for example, networked) to other machines. In a networked deployment, the machine 700 may operate in the capacity of a server machine or a client machine in a server-client network environment, or as a node in a peer-to-peer or distributed network environment. Machine 700 may be embodied as, for example, a server computer, a client computer, a personal computer (PC), a tablet computer, a laptop computer, a netbook, a set-top box (STB), a gaming and/or entertainment system, a smart phone, a mobile device, a wearable device (for example, a smart watch), and an Internet of Things (IoT) device. Further, although only a single machine 700 is illustrated, the term “machine” includes a collection of machines that individually or jointly execute the instructions 716.

The machine 700 may include processors 710, memory 730, and I/O components 750, which may be communicatively coupled via, for example, a bus 702. The bus 702 may include multiple buses coupling various elements of machine 700 via various bus technologies and protocols. In an example, the processors 710 (including, for example, a central processing unit (CPU), a graphics processing unit (GPU), a digital signal processor (DSP), an ASIC, or a suitable combination thereof) may include one or more processors 712a to 712n that may execute the instructions 716 and process data. In some examples, one or more processors 710 may execute instructions provided or identified by one or more other processors 710. The term “processor” includes a multicore processor including cores that may execute instructions contemporaneously. Although FIG. 7 shows multiple processors, the machine 700 may include a single processor with a single core, a single processor with multiple cores (for example, a multicore processor), multiple processors each with a single core, multiple processors each with multiple cores, or any combination thereof. In some examples, the machine 700 may include multiple processors distributed among multiple machines.

The memory/storage 730 may include a main memory 732, a static memory 734, or other memory, and a storage unit 736, both accessible to the processors 710 such as via the bus 702. The storage unit 736 and memory 732, 734 store instructions 716 embodying any one or more of the functions described herein. The memory/storage 730 may also store temporary, intermediate, and/or long-term data for processors 710. The instructions 716 may also reside, completely or partially, within the memory 732, 734, within the storage unit 736, within at least one of the processors 710 (for example, within a command buffer or cache memory), within memory at least one of I/O components 750, or any suitable combination thereof, during execution thereof. Accordingly, the memory 732, 734, the storage unit 736, memory in processors 710, and memory in I/O components 750 are examples of machine-readable media.

As used herein, “machine-readable medium” refers to a device able to temporarily or permanently store instructions and data that cause machine 700 to operate in a specific fashion, and may include, but is not limited to, random-access memory (RAM), read-only memory (ROM), buffer memory, flash memory, optical storage media, magnetic storage media and devices, cache memory, network-accessible or cloud storage, other types of storage and/or any suitable combination thereof. The term “machine-readable medium” applies to a single medium, or combination of multiple media, used to store instructions (for example, instructions 716) for execution by a machine 700 such that the instructions, when executed by one or more processors 710 of the machine 700, cause the machine 700 to perform and one or more of the features described herein. Accordingly, a “machine-readable medium” may refer to a single storage device, as well as “cloud-based” storage systems or storage networks that include multiple storage apparatus or devices. The term “machine-readable medium” excludes signals per se.

The I/O components 750 may include a wide variety of hardware components adapted to receive input, provide output, produce output, transmit information, exchange information, capture measurements, and so on. The specific I/O components 750 included in a particular machine will depend on the type and/or function of the machine. For example, mobile devices such as mobile phones may include a touch input device, whereas a headless server or IoT device may not include such a touch input device. The particular examples of I/O components illustrated in FIG. 7 are in no way limiting, and other types of components may be included in machine 700. The grouping of I/O components 750 are merely for simplifying this discussion, and the grouping is in no way limiting. In various examples, the I/O components 750 may include user output components 752 and user input components 754. User output components 752 may include, for example, display components for displaying information (for example, a liquid crystal display (LCD) or a projector), acoustic components (for example, speakers), haptic components (for example, a vibratory motor or force-feedback device), and/or other signal generators. User input components 754 may include, for example, alphanumeric input components (for example, a keyboard or a touch screen), pointing components (for example, a mouse device, a touchpad, or another pointing instrument), and/or tactile input components (for example, a physical button or a touch screen that provides location and/or force of touches or touch gestures) configured for receiving various user inputs, such as user commands and/or selections.

In some examples, the I/O components 750 may include biometric components 756, motion components 758, environmental components 760, and/or position components 762, among a wide array of other physical sensor components. The biometric components 756 may include, for example, components to detect body expressions (for example, facial expressions, vocal expressions, hand or body gestures, or eye tracking), measure biosignals (for example, heart rate or brain waves), and identify a person (for example, via voice-, retina-, fingerprint-, and/or facial-based identification). The motion components 758 may include, for example, acceleration sensors (for example, an accelerometer) and rotation sensors (for example, a gyroscope). The environmental components 760 may include, for example, illumination sensors, temperature sensors, humidity sensors, pressure sensors (for example, a barometer), acoustic sensors (for example, a microphone used to detect ambient noise), proximity sensors (for example, infrared sensing of nearby objects), and/or other components that may provide indications, measurements, or signals corresponding to a surrounding physical environment. The position components 762 may include, for example, location sensors (for example, a Global Position System (GPS) receiver), altitude sensors (for example, an air pressure sensor from which altitude may be derived), and/or orientation sensors (for example, magnetometers).

The I/O components 750 may include communication components 764, implementing a wide variety of technologies operable to couple the machine 700 to network(s) 770 and/or device(s) 780 via respective communicative couplings 772 and 782. The communication components 764 may include one or more network interface components or other suitable devices to interface with the network(s) 770. The communication components 764 may include, for example, components adapted to provide wired communication, wireless communication, cellular communication, Near Field Communication (NFC), Bluetooth communication, Wi-Fi, and/or communication via other modalities. The device(s) 780 may include other machines or various peripheral devices (for example, coupled via USB).

In some examples, the communication components 764 may detect identifiers or include components adapted to detect identifiers. For example, the communication components 764 may include Radio Frequency Identification (RFID) tag readers, NFC detectors, optical sensors (for example, one- or multi-dimensional bar codes, or other optical codes), and/or acoustic detectors (for example, microphones to identify tagged audio signals). In some examples, location information may be determined based on information from the communication components 764, such as, but not limited to, geo-location via Internet Protocol (IP) address, location via Wi-Fi, cellular, NFC, Bluetooth, or other wireless station identification and/or signal triangulation.

In the preceding detailed description, numerous specific details are set forth by way of examples in order to provide a thorough understanding of the relevant teachings. However, it should be apparent that the present teachings may be practiced without such details. In other instances, well known methods, procedures, components, and/or circuitry have been described at a relatively high-level, without detail, in order to avoid unnecessarily obscuring aspects of the present teachings.

While various embodiments have been described, the description is intended to be exemplary, rather than limiting, and it is understood that many more embodiments and implementations are possible that are within the scope of the embodiments. Although many possible combinations of features are shown in the accompanying figures and discussed in this detailed description, many other combinations of the disclosed features are possible. Any feature of any embodiment may be used in combination with or substituted for any other feature or element in any other embodiment unless specifically restricted. Therefore, it will be understood that any of the features shown and/or discussed in the present disclosure may be implemented together in any suitable combination. Accordingly, the embodiments are not to be restricted except in light of the attached claims and their equivalents. Also, various modifications and changes may be made within the scope of the attached claims.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

The scope of protection is limited solely by the claims that now follow. That scope is intended and should be interpreted to be as broad as is consistent with the ordinary meaning of the language that is used in the claims when interpreted in light of this specification and the prosecution history that follows and to encompass all structural and functional equivalents. Notwithstanding, none of the claims are intended to embrace subject matter that fails to satisfy the requirement of Sections 101, 102, or 103 of the Patent Act, nor should they be interpreted in such a way. Any unintended embracement of such subject matter is hereby disclaimed.

Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element. Furthermore, subsequent limitations referring back to “said element” or “the element” performing certain functions signifies that “said element” or “the element” alone or in combination with additional identical elements in the process, method, article, or apparatus are capable of performing all of the recited functions.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various examples for the purpose of streamlining the disclosure. This method of disclosure is not to be interpreted as reflecting an intention that the claims require more features than are expressly recited in each claim. Rather, as the following claims reflect, inventive subject matter lies in less than all features of a single disclosed example. Thus, the following claims are hereby incorporated into the Detailed Description, with each claim standing on its own as a separately claimed subject matter.

What is claimed is:

1. A data processing system comprising:
a processor; and
a memory storing executable instructions that, when executed, cause the processor alone or in combination with other processors to perform operations of:
receiving, from a user interface of a design application, a first natural language prompt comprising location information for a property and a design for a construction project associated with the property;
retrieving property information from a plurality of data sources using a plurality of data retrieval modules operating in parallel to retrieve a portion of the property information;
training a first black box artificial intelligence (AI) model based on the property information;
generating a preliminary site plan of the property using the first black box AI model, the preliminary site plan representing a current state of the property;
training a second black box AI model based on the preliminary site plan;
analyzing the first natural language prompt using the second AI black box model to generate a proposed design for the construction project;
causing the user interface of the design application to present the proposed design for the construction project;
receiving a second natural language prompt from the user interface of the design application, the second natural language prompt requesting one or more changes to be made to the proposed design;
analyzing the second natural language prompt using the second AI black box model to generate a revised design for the construction project;
receiving an indication from the user interface to finalize the revised design and to output one or more content items based on the finalized design;
training a third black box AI model based on the revised design; and
generating the one or more content items using the third black box AI model.

2. The data processing system of claim 1, wherein the first black box AI model, the second black box AI model, and the third black box AI model are Generative Pre-trained Transformer (GPT) models.

3. The data processing system of claim 1, wherein generating the preliminary site plan of the property further comprises identifying means of access to the property, existing structures on the property, and existing landscaping on the property.

4. The data processing system of claim 1, wherein generating the preliminary site plan of the property further comprises:
generating intermediate design data using a plurality of data analysis modules operating in parallel, and
wherein training the second black box AI model is based on the preliminary site plan and the intermediate data.

5. The data processing system of claim 1, wherein generating the one or more content items using the third black box AI model further comprises:
generating two-dimensional renderings of the proposed design, three-dimensional renderings of the proposed design, or both the two-dimensional renderings and the three-dimensional renderings.

6. The data processing system of claim 1, wherein the property location information comprises a property address or an Assessor's Parcel Number (APN).

7. The data processing system of claim 1, wherein generating the preliminary site plan of the property further comprises:
analyzing the information associated with the property to identify code and setback information for the property.

8. The data processing system of claim 1, wherein analyzing the first natural language prompt using the second AI black box model to generate a proposed design for the construction project further comprises:
adding structural elements, landscape elements, or both structural and landscape elements described in the first natural language prompt to the preliminary site plan.

9. The data processing system of claim 1, wherein the memory further includes instructions configured to cause the processor alone or in combination with other processors to perform operations of:
causing the design application to present one or more selectable design suggestions on the user interface; and
automatically revising the first natural language prompt to include a respective design suggestion responsive to the user selecting the respective design selection.

10. The data processing system of claim 1, wherein the memory further includes instructions configured to cause the processor alone or in combination with other processors to perform operations of:
receiving one or more sample images from the user interface design application, the one or more sample images comprising an example of a structure, landscaping, or both; and
analyzing the first natural language prompt, the preliminary site plan, and the one or more sample images using one or more machine learning models to generate a proposed design for the construction project.

11. A method implemented in a data processing system for a generating designs for construction projects, the method comprising:
receiving, from a user interface of a design application, a first natural language prompt comprising location information for a property and a design for a construction project associated with the property;
retrieving property information from a plurality of data sources using a plurality of data retrieval modules operating in parallel to retrieve a portion of the property information;
training a first black box artificial intelligence (AI) model based on the property information;
generating a preliminary site plan of the property using the first black box AI model, the preliminary site plan representing a current state of the property;
training a second black box AI model based on the preliminary site plan;
analyzing the first natural language prompt using the second AI black box model to generate a proposed design for the construction project;
causing the user interface of the design application to present the proposed design for the construction project;
receiving a second natural language prompt from the user interface of the design application, the second natural language prompt requesting one or more changes to be made to the proposed design;
analyzing the second natural language prompt using the second AI black box model to generate a revised design for the construction project;
receiving an indication from the user interface to finalize the revised design and to output one or more content items based on the finalized design;
training a third black box AI model based on the revised design; and
generating the one or more content items using the third black box AI model.

12. The method of claim 11, wherein the first black box AI model, the second black box AI model, and the third black box AI model are Generative Pre-trained Transformer (GPT) models.

13. The method of claim 11, wherein generating the preliminary site plan of the property further comprises identifying means of access to the property, existing structures on the property, and existing landscaping on the property.

14. The method of claim 11, wherein generating the preliminary site plan of the property further comprises:
generating intermediate design data using a plurality of data analysis modules operating in parallel, and
wherein training the second black box AI model based on the preliminary site plan and the intermediate data.

15. The method of claim 11, wherein generating the one or more content items using the third black box AI model further comprises:
generating two-dimensional renderings of the proposed design, three-dimensional renderings of the proposed design, or both the two-dimensional renderings and the three-dimensional renderings.

16. The method of claim 11, wherein the property location information comprises a property address or an Assessor's Parcel Number (APN).

17. The method of claim 11, wherein generating the preliminary site plan of the property further comprises:
analyzing the information associated with the property to identify code and setback information for the property.

18. A data processing system comprising:
a processor; and
a memory storing executable instructions that, when executed, cause the processor alone or in combination with other processors to perform operations of:
obtaining property location information and a natural language prompt via a user interface of a design application on a client device, the natural language prompt describing a design for a construction project associated with a property, and the property location information identifying a location of the property;
accessing a plurality of data sources to obtain information associated with the property;
analyzing the information associated with the property using one or more machine learning models to generate a preliminary site plan of the property, the preliminary site plan representing a current state of the property;
analyzing the natural language prompt and the preliminary site plan using one or more machine learning models to generate a proposed design for the construction project;
presenting the proposed design on the user interface of the design application on the client device;
receiving, via the user interface of the design application, an indication to finalize the proposed design;
generating content for the proposed design using the one or more machine learning models; and
presenting the content for the proposed design on the user interface of the design application on the client device.

19. The data processing system of claim 18, wherein generating the preliminary site plan of the property further comprises:
analyzing the information associated with the property to identify means of access to the property, existing structures on the property, and existing landscaping on the property.

20. The data processing system of claim 18, wherein generating the preliminary site plan of the property further comprises:
analyzing the information associated with the property to identify code and setback information for the property.
